(19) United States
(12) Patent Application Publication
(10) Pub. No.: US 2026/0353526 A1
(43) Pub. Date: Nov. 5, 2026

(54) RADIO WAVE EMITTING DEVICE

(71) Applicant: Panasonic Intellectual Property Management Co., Ltd., Osaka (JP)

(72) Inventors: SHINJI TAKANO, Gifu (JP); TAKASHI UNO, Shiga (JP); MIKIO FUKUI, Nara (JP)

(21) Appl. No.: 19/148,708

(22) PCT Filed: Dec. 11, 2023
(86) PCT No.: PCT/JP2023/044149

§ 371 Date: Jul. 9, 2026

(30) Foreign Application Priority Data
Feb. 2, 2023 (JP) 2023-014784

(51) Int. Cl. H05B 6/72; H03F 3/24

(52) U.S. Cl. CPC H05B 6/72; H03F 3/245; H03F 2200/171; H03F 2200/451

(57) ABSTRACT

Radio wave radiator (1) includes cavity (10), signal generator (2), signal amplifier (3), radio wave radiation unit (4), controller (5), filter circuit (6), and irreversible circuit (7). Signal generator (2) generates a high-frequency signal. Signal amplifier (3) includes amplifier (31) and amplifies the high-frequency signal. Radio wave radiation unit (4) emits a radio wave into cavity (10) based on the amplified high-frequency signal. Controller (5) controls signal generator (2) and signal amplifier (3). Filter circuit (6) is disposed between amplifier (31) and radio wave radiation unit (4), allows the amplified high-frequency signal to pass therethrough, and attenuates unnecessary radiation generated by signal amplifier (3). Irreversible circuit (7) is disposed between filter circuit (6) and radio wave radiation unit (4).

### TECHNICAL FIELD

The present disclosure relates to a radio wave radiator.

### BACKGROUND ART

PTL 1 discloses a power amplifier for a microwave heater. The power amplifier disclosed in PTL 1 includes an input matching circuit, an amplifier circuit, and an output matching circuit. The amplifier circuit is connected to the input matching circuit and amplifies input signals. The output matching circuit is connected to the amplifier circuit and performs impedance matching. The input matching circuit includes a switch unit and a filter unit and reduces harmonic power.

PTL 2 discloses a microwave oven. The microwave oven disclosed in PTL 2 includes a power supply, a controller, a small-signal microwave generator, a human-machine interface, one or more band-pass filters, a plurality of power amplifiers, and a radio frequency (RF) signal supply device.

### CITATION LIST

### Patent Literature

PTL 1: Chinese Patent Application Publication No. 114245508
PTL 2: U.S. Pat. No. 10,368,404

### SUMMARY OF THE INVENTION

The present disclosure provides a radio wave radiator capable of improving the signal purity of a high-frequency signal transmitted to a radio wave radiation unit.

A radio wave radiator according to one aspect of the present disclosure includes a cavity, a signal generator, a signal amplifier, a radio wave radiation unit, a controller, a filter circuit, and an irreversible circuit.

The signal generator generates a high-frequency signal. The signal amplifier includes an amplifier and amplifies the high-frequency signal. The radio wave radiation unit emits a radio wave into the cavity based on the high-frequency signal amplified by the signal amplifier. The controller controls the signal generator and the signal amplifier.

The filter circuit is disposed between the amplifier and the radio wave radiation unit, allows the high-frequency signal amplified by the signal amplifier to pass therethrough, and attenuates unnecessary radiation generated in the signal amplifier. The irreversible circuit is disposed between the filter circuit and the radio wave radiation unit.

A radio wave radiator according to another aspect of the present disclosure includes a cavity, a signal generator, a signal amplifier, a radio wave radiation unit, a controller, a filter circuit, and an irreversible circuit.

The signal generator generates a high-frequency signal. The signal amplifier includes an amplifier and amplifies the high-frequency signal. The radio wave radiation unit emits a radio wave into the cavity based on the high-frequency signal amplified by the signal amplifier. The controller controls the signal generator and the signal amplifier.

The filter circuit allows the high-frequency signal amplified by the signal amplifier to pass therethrough and attenuates unnecessary radiation generated in the signal amplifier. The irreversible circuit reduces the fluctuation in the characteristics of the filter circuit.

The present disclosure can improve the signal purity of the high-frequency signal transmitted to the radio wave radiation unit.

### BRIEF DESCRIPTION OF THE DRAWINGS

FIG. 1 is a schematic circuit diagram of a radio wave radiator according to a first exemplary embodiment of the present disclosure.

FIG. 2 is a schematic circuit diagram of a signal amplifier (amplifier) in the radio wave radiator according to the first exemplary embodiment.

FIG. 3 is a schematic diagram of a filter circuit in the radio wave radiator according to the first exemplary embodiment.

FIG. 4 is a schematic diagram of a coupler in the radio wave radiator according to the first exemplary embodiment.

FIG. 5 is a schematic diagram of the coupler in the radio wave radiator according to the first exemplary embodiment.

FIG. 6 is a graph illustrating characteristics of the filter circuit of the radio wave radiator illustrated in FIG. 1 with respect to various states of an irradiation target.

FIG. 7 is a partially enlarged view of the graph illustrated in FIG. 6.

FIG. 8 is a graph illustrating characteristics of a filter circuit of a radio wave radiator according to a comparative example with respect to various states of the irradiation target.

FIG. 9 is a partially enlarged view of the graph illustrated in FIG. 8.

FIG. 10 is a graph illustrating a change in a measurement value of traveling wave power of the radio wave radiator in FIG. 1 with respect to a change in the state of the irradiation target.

FIG. 11 is a graph illustrating a change in a measurement value of traveling wave power of a radio wave radiator according to a comparative example with time with respect to a change in the state of the irradiation target.

FIG. 12 is a schematic circuit diagram of a radio wave radiator according to a second exemplary embodiment of the present disclosure.

FIG. 13 is a schematic circuit diagram of a radio wave radiator according to a third exemplary embodiment of the present disclosure.

FIG. 14 is a schematic diagram of a first example of a coupler in the radio wave radiator illustrated in FIG. 13.

FIG. 15 is a schematic diagram of a second example of the coupler in the radio wave radiator illustrated in FIG. 13.

FIG. 16 is a schematic circuit diagram of a filter circuit according to a first modification.

FIG. 17 is a schematic circuit diagram of a filter circuit according to a second modification.

FIG. 18 is a schematic circuit diagram of a filter circuit according to a third modification.

FIG. 19 is a schematic diagram of a filter circuit according to a fourth modification.

FIG. 20 is a schematic circuit diagram of a filter circuit according to a fifth modification.

### DESCRIPTION OF EMBODIMENT

### 1. Exemplary Embodiment

Hereinafter, the exemplary embodiments of the present disclosure will be described with reference to the drawings. In the following exemplary embodiments, for example, detailed description of known matters may be omitted. The same or substantially the same configurations may be denoted by the same reference numerals, and redundant description may be omitted.

### 1.1 First Exemplary Embodiment

### 1.1.1 Configuration

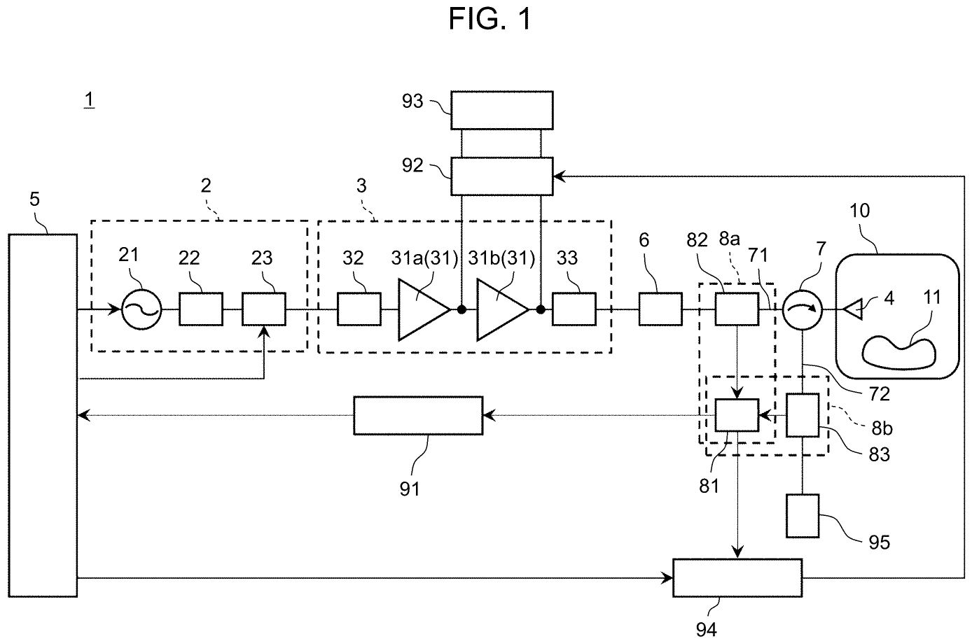

FIG. 1 is a schematic circuit diagram of radio wave radiator 1 according to a first exemplary embodiment of the present disclosure. As illustrated in FIG. 1, radio wave radiator 1 includes cavity 10. Cavity 10 can accommodate irradiation target 11. Irradiation target 11 is a target of radio wave irradiation in radio wave radiator 1.

In the present exemplary embodiment, radio wave radiator 1 is a microwave oven that irradiates irradiation target 11 with radio waves to perform dielectric heating on irradiation target 11. That is, cavity 10 is a heating chamber, and irradiation target 11 is, for example, food.

Cavity 10 confines radio waves (microwaves) in cavity 10. Thus, cavity 10 is made of a material that shields radio waves so that the radio waves do not leak from cavity 10 when irradiation target 11 is irradiated with the radio waves. Examples of the material that shields radio waves include a material that reflects radio waves, such as a metal material, and a material that absorbs radio waves, such as ferrite rubber.

In addition to cavity 10, radio wave radiator 1 includes signal generator 2, signal amplifier 3, radio wave radiation unit 4, controller 5, filter circuit 6, and irreversible circuit 7. In addition, radio wave radiator 1 includes traveling wave power measurement circuit 8a and reflected wave power measurement circuit 8b. Further, radio wave radiator 1 includes analog-digital conversion circuit (AD conversion circuit) 91, bias voltage control circuit 92, DC power supply 93, latch circuit 94, and termination circuit 95.

Signal generator 2 generates a high-frequency signal for generating radio waves. The frequency band of the high-frequency signal is, for example, 1 MHz to 10 GHz. Signal generator 2 includes oscillation circuit 21, matching circuit 22, and variable amplifier 23.

Oscillation circuit 21 generates a high-frequency signal. For example, oscillation circuit 21 may be made up of a phase rocked loop (PLL) frequency synthesizer. Matching circuit 22 is disposed between oscillation circuit 21 and variable amplifier 23. Matching circuit 22 matches the impedance of oscillation circuit 21 with the impedance of variable amplifier 23.

Signal amplifier 3 amplifies the high-frequency signal from signal generator 2. Signal amplifier 3 may be made up of a single amplifier or a plurality of amplifiers. In the present exemplary embodiment, signal amplifier 3 includes amplifier 31a and amplifier 31b. Hereinafter, amplifiers 31a and 31b are collectively referred to as amplifier 31.

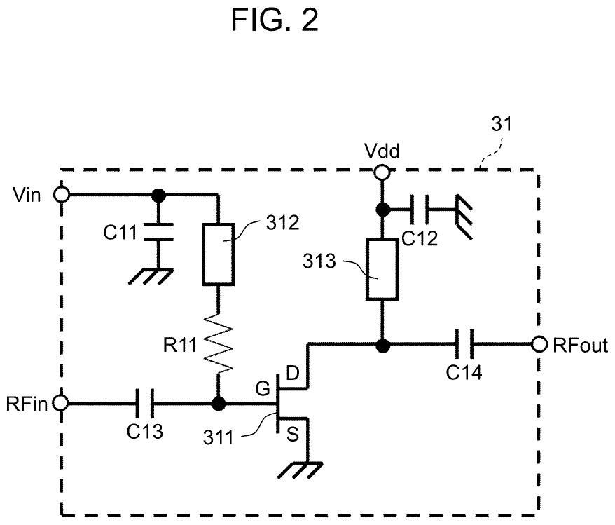

FIG. 2 is a schematic circuit diagram of amplifier 31 included in signal amplifier 3. As illustrated in FIG. 2, amplifier 31 includes transistor 311, choke circuits 312 and 313, capacitors C11, C12, C13, and C14, and resistor R11.

Further, amplifier 31 includes high-frequency input terminal RFin, high-frequency output terminal RFout, gate bias terminal Vin, and power supply terminal Vdd. High-frequency input terminal RFin is connected to signal generator 2. High-frequency output terminal RFout is connected to filter circuit 6 via output matching circuit 33.

Transistor 311 is, for example, an electric field effect transistor. Transistor 311 is a normally-on type transistor that is turned on when the gate voltage is 0 V, for example. The source terminal of transistor 311 is grounded. That is, amplifier 31 is a source-grounded circuit. Transistor 311 amplifies the high-frequency signal input to the gate terminal and outputs the amplified high-frequency signal from the drain terminal.

Amplifier 31 includes a circuit including capacitor C11, choke circuit 312, and resistor R11 disposed in the gate bias path. In FIG. 2, a series circuit including choke circuit 312 and resistor R11 is connected between gate bias terminal Vin and the gate terminal of transistor 311. Capacitor C11 is connected between the ground and the connection point between gate bias terminal Vin and choke circuit 312.

Capacitor C11 functions as a bypass capacitor that reduces power supply noise. Choke circuit 312 includes a transmission line having a length of ¼ of a wavelength of the high-frequency signal. The combination of choke circuit 312 and capacitor C11 increases the impedance of the bias circuit with respect to the high-frequency signal. This prevents leakage of the high-frequency signal to the bias circuit side.

Resistor R11 suppresses abnormal oscillation due to noise of the gate bias. Capacitor C13 is disposed between the gate of transistor 311 and high-frequency input terminal RFin and cuts off the DC component of the bias voltage.

Amplifier 31 includes a circuit including capacitor C12 and choke circuit 313 disposed in a drain bias path. In FIG. 2, choke circuit 313 is connected between power supply terminal Vdd and the drain terminal of transistor 311. Capacitor C12 is connected between the ground and the connection point between power supply terminal Vdd and choke circuit 313, and the ground. Capacitor C12 functions as a bypass capacitor that reduces power supply noise.

Similarly to choke circuit 312, choke circuit 313 includes a transmission line having a length of ¼ of the wavelength of the high-frequency signal. The combination of choke circuit 313 and capacitor C12 increases the impedance of the bias circuit with respect to the high-frequency signal. This prevents leakage of the high-frequency signal to the bias circuit side.

Capacitor C14 is disposed between the drain of transistor 311 and the high-frequency output terminal RFout and cuts off the DC component of the power supply voltage.

As illustrated in FIG. 1, signal amplifier 3 is a multistage amplifier configured by connecting amplifier 31a and amplifier 31b in series. Amplifier 31a is an amplifier of a driver stage (input stage), and amplifier 31b is an amplifier of a final stage (output stage).

The multistage amplifier amplifies minute high-frequency signals from signal generator 2 in stages. For example, amplifier 31a amplifies a 0.1 mW high-frequency signal into a 10 W high-frequency signal, and amplifier 31b amplifies a 10 W high-frequency signal into a 250 W high-frequency signal.

The multistage amplifier includes a plurality of heat generation elements and disperses the heat generation portions, and thus the heat density can be reduced. Thus, the multistage amplifier can dissipate heat with a simple cooling structure. In the present exemplary embodiment, signal amplifier 3 constitutes a high power amplifier.

Signal amplifier 3 further includes input matching circuit 32 disposed in the input path of the high-frequency signal and output matching circuit 33 disposed in the output path of the high-frequency signal. Input matching circuit 32 is disposed between signal generator 2 and amplifier 31a (in particular, high-frequency input terminal RFin (see FIG. 2)).

Output matching circuit 33 is disposed between filter circuit 6 and amplifier 31b (in particular, high-frequency output terminal RFout (see FIG. 2)). Output matching circuit 33 matches the impedance of transistor 311 (see FIG. 2) of amplifier 31b with the impedance on filter circuit 6 side.

Input matching circuit 32 matches the impedance of transistor 311 (see FIG. 2) of amplifier 31a with the impedance of signal generator 2. To match the impedance of amplifier 31a with the impedance of amplifier 31b, an additional matching circuit may be disposed between amplifier 31a and amplifier 31b.

Radio wave radiation unit 4 emits radio waves into cavity 10 based on the high-frequency signal amplified by signal amplifier 3. Radio wave radiation unit 4 is, for example, an antenna. Radio wave radiation unit 4 is disposed in cavity 10, for example, and emits radio waves into cavity 10.

Filter circuit 6 is disposed between amplifier 31 (in particular, amplifier 31b) of signal amplifier 3 and radio wave radiation unit 4. Filter circuit 6 allows the high-frequency signal amplified by signal amplifier 3 to pass therethrough and attenuates unnecessary radiation generated in signal amplifier 3. In the present exemplary embodiment, amplifier 31 of signal amplifier 3 operates in a saturation region. This will be described later.

As a result, harmonics using the high-frequency signal generated in signal generator 2 as a fundamental wave are generated. The unnecessary radiation attenuated by filter circuit 6 includes harmonics of the high-frequency signal amplified by signal amplifier 3. That is, filter circuit 6 attenuates harmonics generated when amplifier 31 of signal amplifier 3 operates in the saturation region.

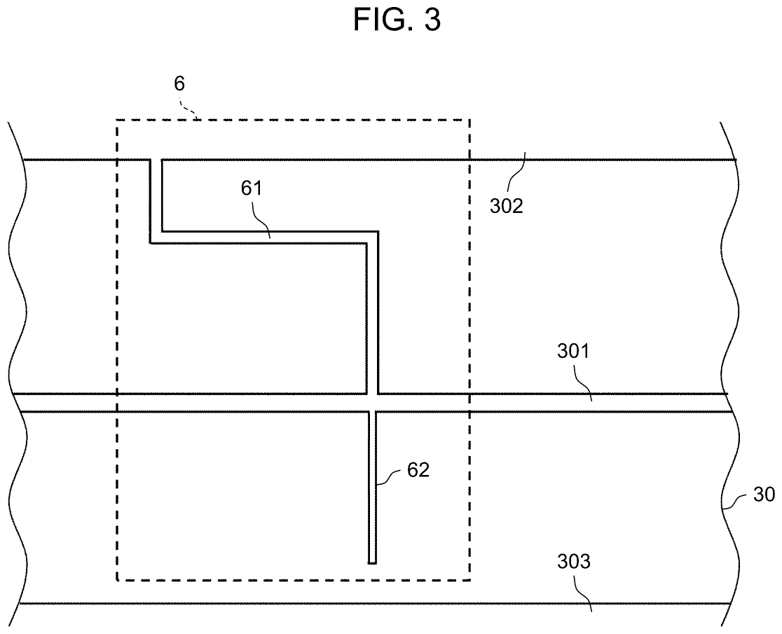

FIG. 3 is a schematic diagram of filter circuit 6. As illustrated in FIG. 3, filter circuit 6 includes band-stop filters 61 and 62. Band-stop filters 61 and 62 attenuate harmonics of the high-frequency signal amplified by signal amplifier 3. Band-stop filters 61 and 62 are distributed constant circuits.

The distributed constant circuit is a circuit in which circuit elements having a line constant per unit length are assumed to be distributed on a transmission line. When the wavelength of the signal propagating through the transmission line cannot be considered to be sufficiently large with respect to the circuit shape, the distributed constant circuit can be used. In the distributed constant circuit, a filter can be formed only by wiring such as a microstrip line.

Band-stop filters 61 and 62 are disposed on circuit board 30 of signal amplifier 3. For example, circuit board 30 includes transmission line 301 and grounds 302 and 303. Transmission line 301 transmits the high-frequency signal amplified by signal amplifier 3.

Band-stop filter 61 is a short stub that attenuates the second harmonic of the high-frequency signal amplified by signal amplifier 3. Band-stop filter 61 includes, for example, a microstrip line extending from transmission line 301 to ground 302 and connected to ground 302.

Assuming that the length of the short stub is L1 and the wavelength of the signal propagating through transmission line 301 is λ, the short stub functions as an inductor when L1<λ/4. When L1=λ/4, the short stub has an open impedance. When λ/4<L1<λ/2, the short stub functions as a capacitor. When L1=λ/2, the short stub has a short circuit impedance.

Length L1 of the short stub is set based on ¼ of wavelength λ of the high-frequency signal amplified by signal amplifier 3. Thus, the short stub has an open impedance with respect to the high-frequency signal amplified by signal amplifier 3. On the other hand, the short stub has a short circuit impedance with respect to the second harmonic of the high-frequency signal amplified by signal amplifier 3.

As a result, band-stop filter 61 allows the high-frequency signal amplified by signal amplifier 3 to pass therethrough and attenuates the second harmonic of the high-frequency signal amplified by signal amplifier 3. For example, when the frequency of the high-frequency signal amplified by signal amplifier 3 is 2450 MHz, the frequency of the second harmonic wave is 4900 MHz.

The line impedance is defined by the line width of the short stub. Depending on the line width of the short stub, the Q factor of band-stop filter 61 can be changed to slightly adjust the attenuation band.

The line width of the short stub may be made sufficiently smaller than the width of transmission line 301 to increase the line impedance. The line width of the short stub may be made larger than the width of transmission line 301 to lower the line impedance. The shape of the short stub may be designed according to a desired attenuation characteristic by partially or continuously changing the line width of the short stub.

Band-stop filter 62 is an open stub that attenuates the third harmonic of the high-frequency signal amplified by signal amplifier 3. Band-stop filter 62 includes, for example, a microstrip line extending from transmission line 301 toward ground 303 but not connected to ground 303.

Assuming that the length of the open stub is L2, and the wavelength of the signal propagating through transmission line 301 is λ, the open stub functions as a capacitor when L2<λ/4. When L2=λ/4, the open stub has a short circuit impedance. When λ/4<L2<λ/2, the open stub functions as an inductor. When L2=λ/2, the open stub has an open impedance.

Length L2 of the open stub is set based on ¼ of wavelength λ of the third harmonic of the high-frequency signal amplified by signal amplifier 3. Thus, the open stub functions as a capacitor with respect to the high-frequency signal amplified by signal amplifier 3. On the other hand, the open stub has a short circuit impedance with respect to the third harmonic of the high-frequency signal amplified by signal amplifier 3.

As a result, band-stop filter 62 allows the high-frequency signal amplified by signal amplifier 3 to pass therethrough and attenuates the third harmonic of the high-frequency signal amplified by signal amplifier 3. For example, when the frequency of the high-frequency signal amplified by signal amplifier 3 is 2450 MHz, the frequency of the third harmonic wave is 7350 MHz.

The line impedance is defined by the line width of the open stub. Depending on the line width of the open stub, the Q factor of band-stop filter 62 can be changed to slightly adjust the attenuation band.

The line width of the short stub may be made sufficiently smaller than the width of transmission line 301 to increase the line impedance. The line width of the short stub may be made larger than the width of transmission line 301 to lower the line impedance. The shape of the short stub may be designed according to a desired attenuation characteristic by partially or continuously changing the line width of the short stub.

In this manner, filter circuit 6 allows the high-frequency signal having a frequency of 2450 MHz amplified by signal amplifier 3 to pass therethrough and attenuates unnecessary radiation (second harmonic with frequency of 4900 MHz and third harmonic with frequency of 7350 MHz) generated in signal amplifier 3.

The description returns to FIG. 1. Irreversible circuit 7 is disposed between filter circuit 6 and radio wave radiation unit 4. Irreversible circuit 7 includes first transmission line 71 and second transmission line 72 that are insulated from each other. Irreversible circuit 7 separates a traveling wave and a reflected wave. First transmission line 71 transmits the traveling wave to radio wave radiation unit 4. Second transmission line 72 transmits the reflected wave to termination circuit 95. Irreversible circuit 7 is, for example, a circulator.

The traveling wave is the high-frequency signal amplified by signal amplifier 3. That is, the traveling wave is the high-frequency signal supplied to the radio wave radiation unit 4 to emit radio waves into cavity 10.

The reflected wave is the high-frequency signal flowing backward from radio wave radiation unit 4. The reflected wave is generated by radio waves that are not radiated from radio wave radiation unit 4 into cavity 10 because of impedance mismatch, for example. Alternatively, the reflected wave is generated by a radio wave that is not absorbed by irradiation target 11 but is reflected in cavity 10 and returns to radio wave radiation unit 4 among the radio waves emitted into cavity 10 by radio wave radiation unit 4.

Traveling wave power measurement circuit 8a measures the power of the traveling wave in first transmission line 71. Traveling wave power measurement circuit 8a includes detector circuit 81 and coupler 82. Reflected wave power measurement circuit 8b measures the power of the reflected wave in second transmission line 72. Reflected wave power measurement circuit 8b includes detector circuit 81 and coupler 83.

In radio wave radiator 1, detector circuit 81 functions as both traveling wave power measurement circuit 8a and reflected wave power measurement circuit 8b. Hereinafter, the power of the traveling wave and the power of the reflected wave are referred to as traveling wave power and reflected wave power, respectively.

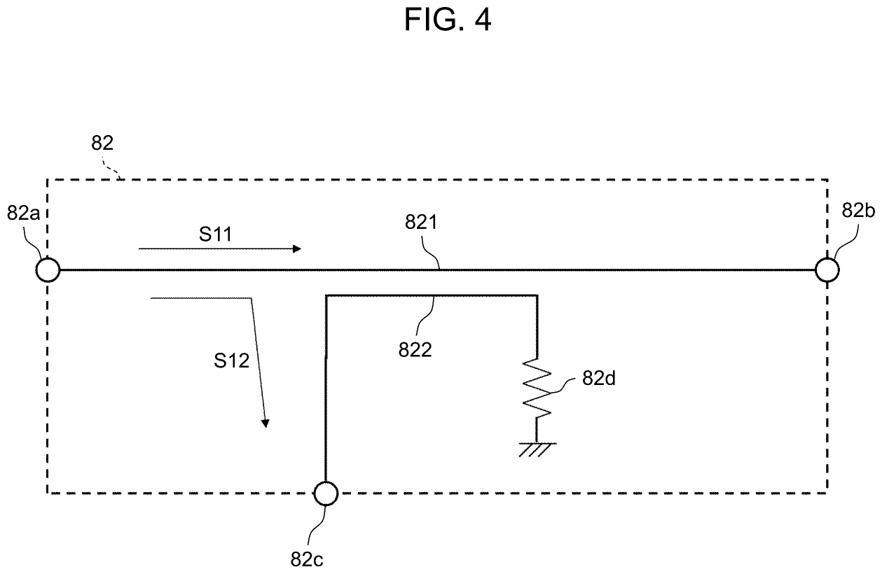

Coupler 82 is disposed between filter circuit 6 and irreversible circuit 7 and detects the traveling wave. In other words, coupler 82 is disposed on first transmission line 71. FIG. 4 is a schematic diagram of coupler 82. Coupler 82 illustrated in FIG. 4 is a directional coupler. Coupler 82 includes input port 82a, output port 82b, coupling port 82c, termination resistor 82d, first line 821, and second line 822.

First line 821 is disposed between input port 82a and output port 82b. Second line 822 is disposed between coupling port 82c and termination resistor 82d. Second line 822 is electromagnetically coupled to first line 821 partially parallel to first line 821.

Traveling wave S11 is input to input port 82a and propagates through first line 821. Coupler 82 outputs a part of traveling wave S11 as traveling wave coupling signal S12 from coupling port 82c via second line 822. The magnitude of traveling wave coupling signal S12 is proportional to the power of traveling wave S11.

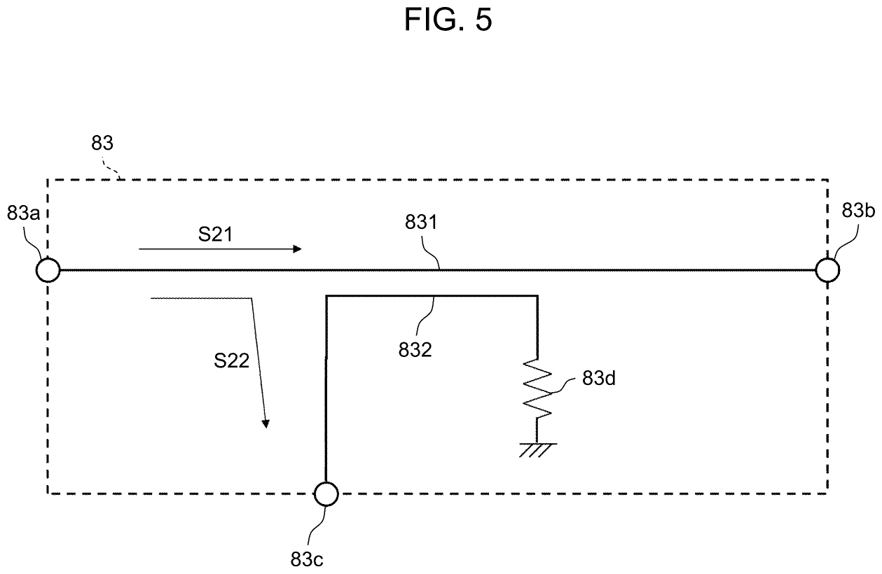

Coupler 83 is disposed between irreversible circuit 7 and termination circuit 95 and detects the reflected wave. In other words, coupler 83 is disposed on second transmission line 72. FIG. 5 is a schematic diagram of coupler 83. Coupler 83 illustrated in FIG. 5 is a directional coupler. Coupler 83 includes input port 83a, output port 83b, coupling port 83c, termination resistor 83d, first line 831, and second line 832.

First line 831 is disposed between input port 83a and output port 83b. Second line 832 is disposed between coupling port 83c and termination resistor 83d. First line 832 is electromagnetically coupled to first line 831 partially parallel to first line 831.

Reflected wave S21 is input to input port 83a and propagates through first line 831. Coupler 83 outputs a part of reflected wave S21 as reflected wave coupling signal S22 from coupling port 83c via second line 832. The magnitude of reflected wave coupling signal S22 is proportional to the power of reflected wave S21.

Since couplers 82 and 83 are disposed on first transmission line 71 and second transmission line 72 electrically insulated from each other, respectively, the traveling wave and the reflected wave are insulated from each other. Thus, couplers 82 and 83 do not require strict directionality. Therefore, couplers 82 and 83 can be easily formed. For example, couplers 82 and 83 can be easily formed with a pattern on a printed circuit board.

Detector circuit 81 measures traveling wave power and reflected wave power. Specifically, detector circuit 81 generates a traveling wave power measurement signal, which is an analog signal corresponding to the traveling wave power, based on traveling wave coupling signal S12 from coupler 82. The traveling wave power measurement signal is transmitted to AD conversion circuit 91 and latch circuit 94.

Based on reflected wave coupling signal S22 from coupler 83, detector circuit 81 generates a reflected wave power measurement signal that is an analog signal corresponding to the reflected wave power. The reflected wave power measurement signal is transmitted to AD conversion circuit 91 and latch circuit 94.

AD conversion circuit 91 converts the traveling wave power measurement signal into a digital signal and transmits the digital signal to controller 5. AD conversion circuit 91 converts the reflected wave power measurement signal into a digital signal and transmits the digital signal to controller 5.

DC power supply 93 supplies a bias voltage to the drain terminal of transistor 311 (see FIG. 2) of amplifier 31a and the drain terminal of transistor 311 of amplifier 31b. Bias voltage control circuit 92 controls these bias voltages.

Bias voltage control circuit 92 includes a first switch element and a second switch element. The first switch element is disposed between DC power supply 93 and the drain terminal (more specifically, power supply terminal Vdd in FIG. 2) of transistor 311. The second switch element is disposed between DC power supply 93 and the drain terminal (more specifically, power supply terminal Vdd in FIG. 2) of transistor 311. These switch elements are, for example, transistors.

The bias voltage for amplifier 31a and the bias voltage for amplifier 31b may be different depending on the power levels output from amplifiers 31a and 31b and the type of transistor 311. For example, the bias voltage for amplifier 31a having a relatively low power level may be 30 V, and the bias voltage for amplifier 31b having a relatively high power level may be 48 V.

DC power supply 93 generates one or more predetermined DC voltages from the AC voltage of the commercial AC power supply. The DC voltage from DC power supply 93 is used as a bias voltage for amplifiers 31a and 31b and a driving power supply for signal generator 2, controller 5, bias voltage control circuit 92, and the like.

Latch circuit 94 controls bias voltage control circuit 92. When the magnitude of the traveling wave power measurement signal or the magnitude of the reflected wave power measurement signal has exceeded a threshold, latch circuit 94 turns off bias voltage control circuit 92. That is, when the traveling wave or the reflected wave has a predetermined magnitude, latch circuit 94 turns off bias voltage control circuit 92.

When receiving the reset signal from controller 5, latch circuit 94 turns on bias voltage control circuit 92. When bias voltage control circuit 92 is turned on, the first and second switch elements are turned on. In this case, a bias voltage is supplied from DC power supply 93 to the drain terminal of transistor 311. As a result, amplifiers 31a and 31b operate, and radio waves are emitted from radio wave radiation unit 4.

When bias voltage control circuit 92 is turned off, the first and second switch elements are turned off. In this case, the bias voltage is not supplied from DC power supply 93 to the drain terminal of transistor 311. As a result, amplifiers 31a and 31b stop, and the emission of the radio waves from the radio wave radiation unit 4 stops.

The reflected wave separated by irreversible circuit 7 reaches termination circuit 95 via coupler 83. Termination circuit 95 includes a termination resistor and consumes the reflected wave as heat.

Controller 5 controls signal generator 2 and signal amplifier 3. As a result, radio waves are emitted from the radio wave radiation unit 4 into cavity 10. In the present exemplary embodiment, controller 5 operates transistors 311 included in amplifiers 31a and 31b in the saturation region. This can improve the power efficiency of amplifiers 31a and 31b.

When amplifier 31 operates in the saturation region, the signal waveform is distorted. This generates harmonics using the high-frequency signal generated by signal generator 2 as a fundamental wave. As described above, filter circuit 6 attenuates unnecessary radiation. The unnecessary radiation includes harmonics of the high-frequency signal amplified by signal amplifier 3. That is, filter circuit 6 attenuates harmonics generated when amplifier 31 operates in the saturation region.

Controller 5 receives the traveling wave power measurement signal and the reflected wave power measurement signal converted into digital signals by AD conversion circuit 91. Controller 5 may control signal generator 2 and signal amplifier 3 based on the traveling wave power indicated by the traveling wave power measurement signal and the reflected wave power indicated by the reflected wave power measurement signal.

Controller 5 may cause signal generator 2 and signal amplifier 3 to perform a normal operation based on the traveling wave power indicated by the traveling wave power measurement signal. In the normal operation, controller 5 may control signal generator 2 and signal amplifier 3 such that the traveling wave power becomes the target power.

Controller 5 may control the power of the radio wave emitted by the radio wave radiation unit 4 by causing signal generator 2 to adjust the magnitude of the high-frequency signal. Controller 5 may control the output of the radio wave emitted by the radio wave radiation unit 4 by changing the amplification factor of signal amplifier 3, changing the voltage of the internal power supply connected to signal amplifier 3, or the like. Controller 5 may cause variable amplifier 23 to adjust the magnitude of the high-frequency signal.

Controller 5 may control the frequency of the radio wave emitted by the radio wave radiation unit 4 by causing signal generator 2 to adjust the frequency of the high-frequency signal. The frequency of the radio wave emitted by the radio wave radiation unit 4 may be appropriately selected from a frequency band that can be used for dielectric heating of irradiation target 11.

Controller 5 may cause signal generator 2 and signal amplifier 3 to perform a protection operation based on the reflected wave power indicated by the reflected wave power measurement signal. For example, controller 5 determines whether signal amplifier 3 needs to be protected based on the reflected wave power. Controller 5 may determine whether signal amplifier 3 needs to be protected based on whether the reflected wave power is more than or equal to a threshold. When determining that the reflected wave power is more than or equal to the threshold, controller 5 executes the protection operation.

In the protection operation, controller 5 may stop at least one of signal generator 2 and signal amplifier 3. In the present exemplary embodiment, latch circuit 94 causes signal amplifier 3 to stop the operation by turning off bias voltage control circuit 92 before controller 5. When determining that signal amplifier 3 does not need to be protected, controller 5 may output a reset signal to latch circuit 94 to end the protection operation.

Controller 5 determines whether a correction operation of signal generator 2 and signal amplifier 3 is necessary based on the reflected wave power. When determining that the correction operation is necessary, controller 5 executes the correction operation. For the correction operation, controller 5 controls signal generator 2 or signal amplifier 3 so that the traveling wave power to be supplied to irradiation target 11 has a target value in consideration of the reflected wave power.

Because of the generation of the reflected wave power, the traveling wave power to be supplied to irradiation target 11 may differ from the target value. In this case, controller 5 adjusts the high-frequency signal to be output from at least one of signal generator 2 and signal amplifier 3 to correct the power of the radio wave to be emitted by radio wave radiation unit 4. As a result, controller 5 adjusts the amount of power to be supplied to irradiation target 11 so that the amount of power falls within the target range.

Controller 5 may include a microcontroller including one or more microprocessors and a memory. Controller 5 may include, for example, a field-programmable gate array (FPGA), an application specific integrated circuit (ASIC), or the like.

### 1.1.2 Evaluation

As described above, in radio wave radiator 1 of FIG. 1, filter circuit 6 is disposed between signal amplifier 3 and radio wave radiation unit 4. Filter circuit 6 allows the high-frequency signal amplified by signal amplifier 3 to pass therethrough and attenuates unnecessary radiation generated in signal amplifier 3. Filter circuit 6 is usually designed with a determined load impedance and maintains optimum characteristics for the determined load impedance.

However, depending on the state of irradiation target 11 in cavity 10 (for example, the type of irradiation target 11 and the heating state), the electrical properties (for example, relative dielectric constant) of irradiation target 11 change. That is, the load impedance of irradiation target 11 varies depending on the type of irradiation target 11 and changes in the process of the heat treatment.

The change in the state of irradiation target 11, that is, the change in the load impedance of irradiation target 11 fluctuates the characteristics of filter circuit 6. The characteristics of filter circuit 6 are characteristics that cause the high-frequency signal amplified by signal amplifier 3 to pass through the filter circuit 6 and attenuate unnecessary radiation generated in signal amplifier 3.

Radio wave radiator 1 includes irreversible circuit 7 disposed between filter circuit 6 and radio wave radiation unit 4. Irreversible circuit 7 transmits the signal from filter circuit 6 to radio wave radiation unit 4 and blocks the signal from radio wave radiation unit 4 to filter circuit 6.

Irreversible circuit 7 substantially makes the impedance as seen from filter circuit 6 to irreversible circuit 7 less likely to be affected by the load impedance fluctuation. Thus, filter circuit 6 is hardly affected by a change in the state of irradiation target 11 in cavity 10.

That is, since irreversible circuit 7 is disposed at the subsequent stage of filter circuit 6, the characteristics (signal passing characteristics) of filter circuit 6 are kept constant regardless of the state of irradiation target 11. As a result, the characteristics of filter circuit 6 can be maintained substantially with no change. That is, filter circuit 6 can maintain optimum signal passing characteristics with respect to the determined load impedance.

In this manner, in radio wave radiator 1, the fluctuation in the characteristics of filter circuit 6 depending on the state of irradiation target 11 can be suppressed. As a result, the characteristics of filter circuit 6 are stabilized, and the signal purity of the high-frequency signal transmitted to the radio wave radiation unit 4 can be improved. That is, filter circuit 6 can stably remove unnecessary radiation from the high-frequency signal to be transmitted to radio wave radiation unit 4.

Further, by irreversible circuit 7, not only the characteristics of filter circuit 6 but also the characteristics of signal amplifier 3 are kept constant regardless of the state of irradiation target 11. As a result, the power efficiency of signal amplifier 3 is stabilized.

Hereinafter, for radio wave radiator 1 and a radio wave radiator of a comparative example, the characteristics of filter circuit 6 when the state of irradiation target 11 is different are evaluated by simulation. The radio wave radiator of the comparative example has the same configuration as radio wave radiator 1 of FIG. 1 except that irreversible circuit 7 is not provided. With this configuration, the effect of irreversible circuit 7 in radio wave radiator 1 can be confirmed.

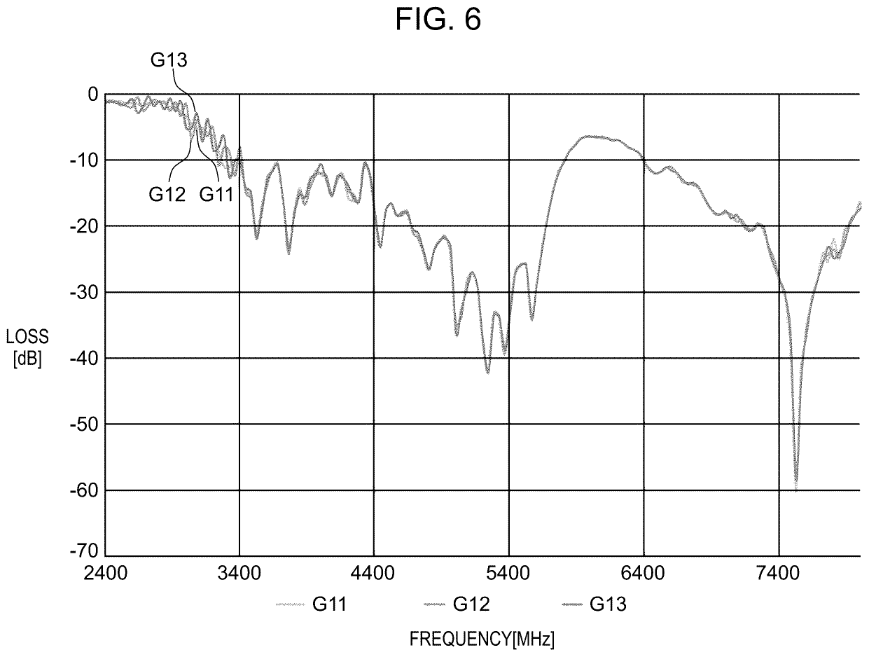

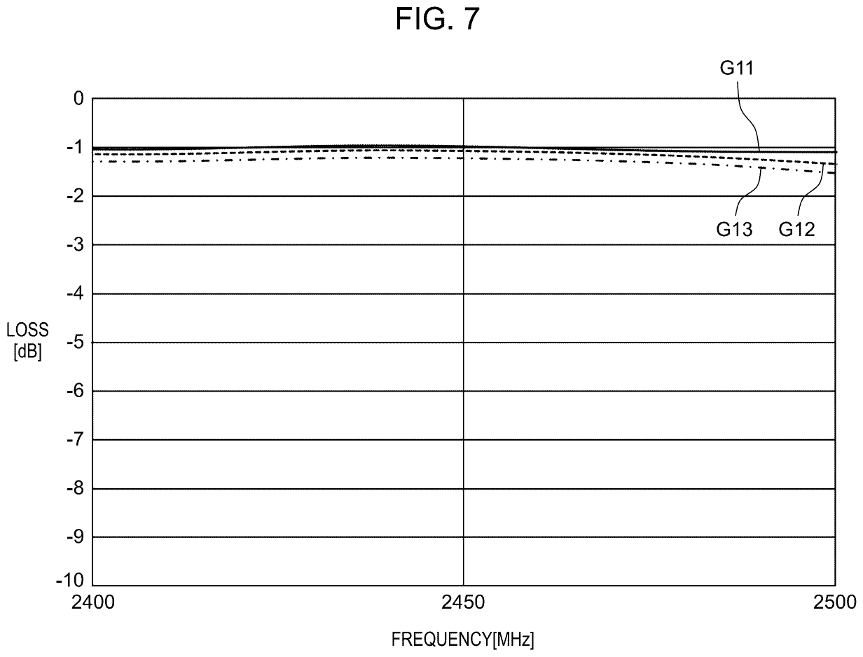

FIG. 6 is a graph illustrating characteristics of filter circuit 6 of radio wave radiator 1 with respect to various states of irradiation target 11. FIG. 7 is a partially enlarged view of a frequency band of 2400 MHz to 2500 MHz in FIG. 6.

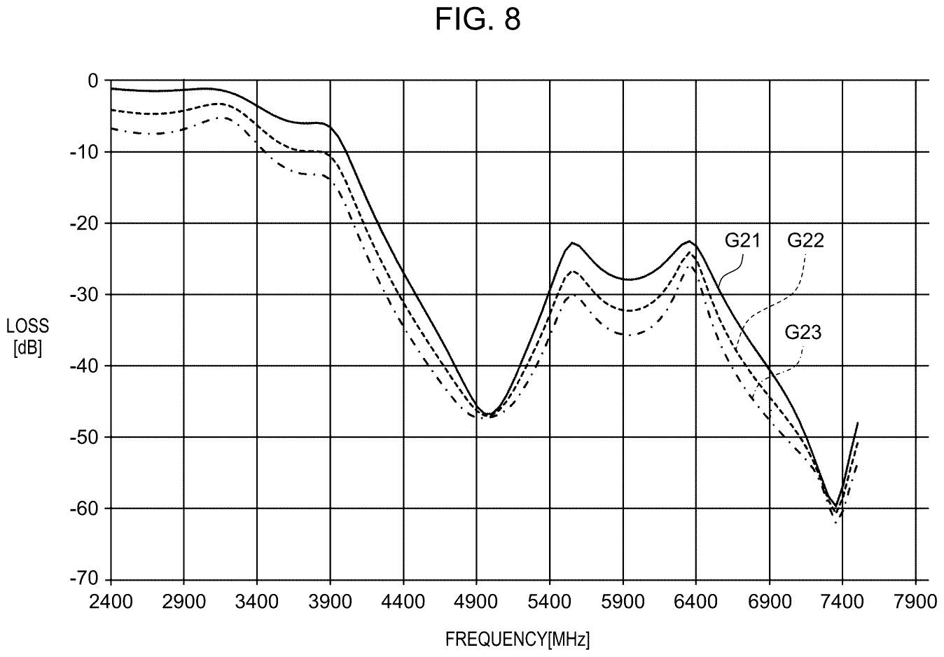

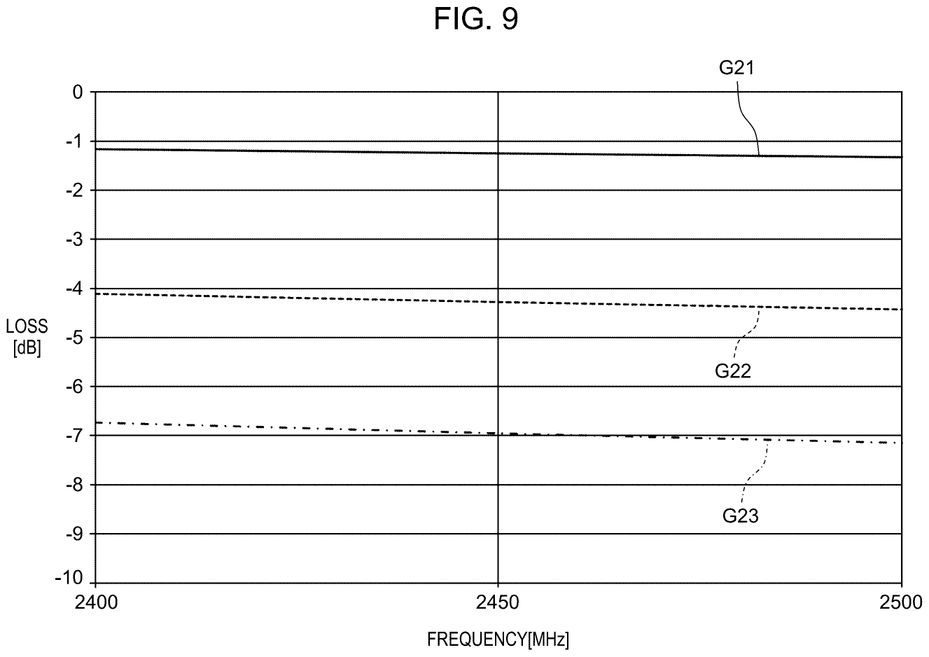

FIG. 8 is a graph illustrating characteristics of filter circuit 6 of the radio wave radiator according to the comparative example with respect to various states of irradiation target 11. FIG. 9 is a partially enlarged view of a frequency band of 2400 MHz to 2500 MHz in FIG. 8.

In FIGS. 6 to 9, the horizontal axis represents the frequency [MHz], and the vertical axis represents the loss (insertion loss) [dB]. In FIGS. 6 and 7, graphs G11, G12, and G13 illustrate cases where the load impedance is 60Ω, 100Ω, and 150Ω, respectively. In FIGS. 8 and 9, graphs G21, G22, and G23 illustrate cases where the load impedance is 60Ω, 100Ω, and 150Ω, respectively.

In the present exemplary embodiment, filter circuit 6 allows a high-frequency signal having a frequency of 2450 MHz to pass therethrough and attenuates unnecessary radiation generated in signal amplifier 3. In this case, the unnecessary radiation is the second harmonic having a frequency of 4900 MHz and the third harmonic having a frequency of 7350 MHz.

As illustrated in FIGS. 6 and 8, the loss is small in the vicinity of the frequency of 2450 MHz, and the loss is large in the vicinity of the frequency of 4900 MHz and the vicinity of the frequency of 7350 MHz. As illustrated in FIG. 6, graphs G11, G12, and G13 are almost the same. As illustrated in FIG. 7, in the frequency band of 2400 MHz to 2500 MHz, the loss is about −1 dB in any case where the load impedance is 60Ω, 100Ω, or 150Ω.

That is, in radio wave radiator 1, the characteristics of filter circuit 6 are hardly affected by the load impedance fluctuation because filter circuit 6 is insulated from irradiation target 11 (load) by irreversible circuit 7. Thus, the influence on the power loss of radio wave radiator 1 is reduced.

Graphs G21, G22, and G23 illustrated in FIG. 8 are different from those illustrated in FIG. 6. From FIG. 9, in the frequency band (2400 MHz to 2500 MHz) of the high-frequency signal amplified by signal amplifier 3, the losses [dB] at the load impedances of 60Ω, 100Ω, and 150Ω with respect to the frequencies of 2400 MHz, 2450 MHz, and 2500 MHz are as shown in Table 1.

TABLE 1

| Loss [dB] | 60Ω | 100Ω | 150Ω |
|---|---|---|---|
| 2400 MHz | −1.17 | −4.11 | −6.73 |
| 2450 MHz | −1.25 | −4.28 | −6.95 |
| 2500 MHz | −1.33 | −4.43 | −7.15 |

When the input power is 250 W, the power loss [W] at filter circuit 6 for each frequency of 2400 MHz, 2450 MHz, and 2500 MHz is as shown in Table 2 below.

TABLE 2

| Power loss [W] | 60Ω | 100Ω | 150Ω |
|---|---|---|---|
| 2400 MHz | 59.0 | 152.9 | 196.9 |
| 2450 MHz | 62.5 | 156.7 | 199.5 |
| 2500 MHz | 65.9 | 159.8 | 201.8 |

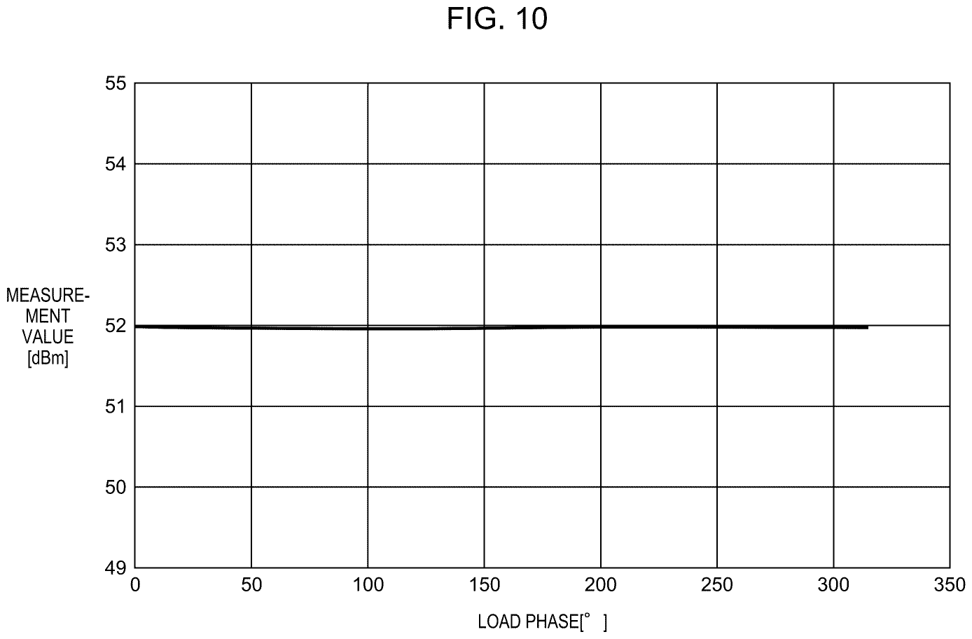

As illustrated in FIGS. 8 and 10, in the radio wave radiator of the comparative example, filter circuit 6 is not insulated from irradiation target 11 (load), and the characteristics of filter circuit 6 are affected by the load impedance fluctuation. That is, the loss in filter circuit 6 increases as the load impedance increases. As a result, the power loss in filter circuit 6 increases (see Table 2).

In this manner, in radio wave radiator 1, irreversible circuit 7 can suppress the fluctuation in the characteristics of filter circuit 6 depending on the state of irradiation target 11.

As described above, in radio wave radiator 1, irreversible circuit 7 includes first transmission line 71 and second transmission line 72 insulated from each other. First transmission line 71 transmits traveling wave to radio wave radiation unit 4, and second transmission line 72 transmits the reflected wave to termination circuit 95. Traveling wave power measurement circuit 8a measures traveling wave power in first transmission line 71, and reflected wave power measurement circuit 8b measures reflected wave power in second transmission line 72.

With this configuration, traveling wave power measurement circuit 8a can measure the traveling wave power without being affected by the reflected wave. As a result, radio wave radiator 1 can improve the accuracy of the measurement of the traveling wave power and the measurement of the reflected wave power.

Hereinafter, the simulation results regarding the change in the measurement value of the traveling wave power with respect to the change in the state of the irradiation target in radio wave radiator 1 and the radio wave radiator of the comparative example are described. The effect of radio wave radiator 1 was checked by evaluating the results. The radio wave radiator of the comparative example is different from radio wave radiator 1 of FIG. 1 in that irreversible circuit 7 is not provided.

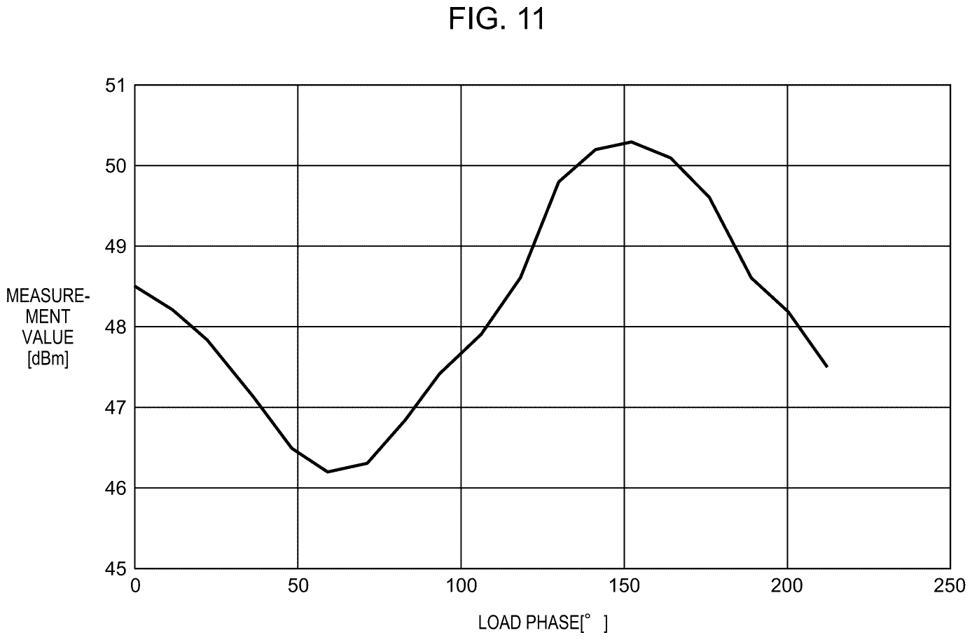

FIG. 10 is a graph illustrating a change in the measurement value of the traveling wave power with respect to a change in the state of irradiation target 11 in radio wave radiator 1. FIG. 11 is a graph illustrating a change in the measurement value of the traveling wave power with respect to a change in the state of irradiation target 11 in the radio wave radiator of the comparative example.

In FIGS. 10 and 11, the horizontal axis represents the load phase [°], and the vertical axis represents the measurement value [dBm] of the traveling wave power. The load phase is a parameter corresponding to the state of irradiation target 11, and is a phase difference generated between the traveling wave and the reflected wave because of a change in the state of irradiation target 11.

As illustrated in FIGS. 10 and 11, in the case of radio wave radiator 1, the fluctuation of the measurement value of the traveling wave power is smaller than that of the radio wave radiator of the comparative example. Since the radio wave radiator of the comparative example does not include irreversible circuit 7, reflected wave S21 is coupled to traveling wave S11 in coupler 82. This causes reflected wave S21 to fluctuate traveling wave coupling signal S12. That is, the detection accuracy of traveling wave coupling signal S12 deteriorates.

As illustrated in FIG. 11, leakage of reflected wave S21 from first line 831 to second line 832 changes the phase difference between traveling wave S11 and reflected wave S21. This change in the phase difference causes an error of about +2 dBm in the measurement value.

On the other hand, since radio wave radiator 1 includes irreversible circuit 7, first transmission line 71 and second transmission line 72 are insulated from each other. Thus, leakage of reflected wave S21 from first line 831 to second line 832 is extremely small. As a result, as illustrated in FIG. 10, an error due to a change in phase difference between traveling wave S11 and reflected wave S21 hardly occurs in the measurement value. That is, radio wave radiator 1 can improve the measurement accuracy of the traveling wave power.

### 1.1.3 Effects and the Like

Radio wave radiator 1 according to the present exemplary embodiment includes cavity 10, signal generator 2, signal amplifier 3, radio wave radiation unit 4, controller 5, filter circuit 6, and irreversible circuit 7.

Signal generator 2 generates a high-frequency signal. Signal amplifier 3 includes amplifier 31 and amplifies the high-frequency signal. Radio wave radiation unit 4 emits radio waves into cavity 10 based on the high-frequency signal amplified by signal amplifier 3. Controller 5 controls signal generator 2 and signal amplifier 3.

Filter circuit 6 is disposed between amplifier 31 and radio wave radiation unit 4, allows the high-frequency signal amplified by signal amplifier 3 to pass therethrough, and attenuates unnecessary radiation generated in signal amplifier 3. Irreversible circuit 7 is disposed between filter circuit 6 and radio wave radiation unit 4.

This configuration can suppress the fluctuation in the characteristics of filter circuit 6 depending on the state of irradiation target 11. Thus, the signal purity of the high-frequency signal transmitted to radio wave radiation unit 4 can be improved.

In radio wave radiator 1, controller 5 operates amplifier 31 of signal amplifier 3 in a saturation region. This configuration can improve the power efficiency of signal amplifier 3.

In radio wave radiator 1, unnecessary radiation includes harmonics of the high-frequency signal generated when amplifier 31 of signal amplifier 3 operates in the saturation region. This configuration can improve the signal purity of the high-frequency signal transmitted to radio wave radiation unit 4.

Radio wave radiator 1 further includes a traveling wave power measurement circuit 8a and reflected wave power measurement circuit 8b. Traveling wave power measurement circuit 8a measures traveling wave power. The traveling wave power is power of a traveling wave, and the traveling wave is the high-frequency signal amplified by signal amplifier 3. Reflected wave power measurement circuit 8b measures reflected wave power. The reflected wave power is power of a reflected wave, and the reflected wave is the high-frequency signal flowing backward from radio wave radiation unit 4.

Irreversible circuit 7 includes first transmission line 71 and second transmission line 72 insulated from each other. First transmission line 71 transmits the traveling wave to radio wave radiation unit 4. Second transmission line 72 transmits the reflected wave to termination circuit 95. Traveling wave power measurement circuit 8a measures traveling wave power on first transmission line 71. Reflected wave power measurement circuit 8b measures reflected wave power on second transmission line 72.

Controller 5 controls signal generator 2 and signal amplifier 3 based on the traveling wave power and the reflected wave power. This configuration can improve accuracy of measurement of the traveling wave power and measurement of the reflected wave power.

In radio wave radiator 1, filter circuit 6 includes band-stop filters 61 and 62 that are distributed constant circuits. Band-stop filters 61 and 62 are disposed on circuit board 30 of signal amplifier 3. This configuration enables downsizing of radio wave radiator 1. This configuration is suitable for a radio wave radiator capable of handling high-frequency power of more than or equal to 10 W.

In radio wave radiator 1, filter circuit 6 includes band-stop filters 61 and 62. The band-stop filter attenuates harmonics of the high-frequency signal. This configuration enables downsizing of filter circuit 6. This configuration is suitable for a radio wave radiator capable of handling high-frequency power of more than or equal to 10 W.

In radio wave radiator 1, each of band-stop filters 61 and 62 includes a short stub and an open stub. The short stub attenuates the second harmonic of the high-frequency signal. The open stub attenuates the third harmonic of the high-frequency signal. This configuration enables downsizing of filter circuit 6. This configuration is suitable for a radio wave radiator capable of handling high-frequency power of more than or equal to 10 W.

Radio wave radiator 1 according to another aspect includes cavity 10, signal generator 2, signal amplifier 3, radio wave radiation unit 4, controller 5, filter circuit 6, and irreversible circuit 7.

Signal generator 2 generates a high-frequency signal. Signal amplifier 3 includes amplifier 31 and amplifies the high-frequency signal. Radio wave radiation unit 4 emits radio waves into cavity 10 based on the high-frequency signal amplified by signal amplifier 3. Controller 5 controls signal generator 2 and signal amplifier 3.

Filter circuit 6 allows the high-frequency signal amplified by signal amplifier 3 to pass therethrough and attenuates unnecessary radiation generated in signal amplifier 3. Irreversible circuit 7 reduces the fluctuation in the characteristics of filter circuit 6. This configuration can improve the signal purity of the high-frequency signal transmitted to radio wave radiation unit 4.

### 1.2 Second Exemplary Embodiment

### 1.2.1 Configuration

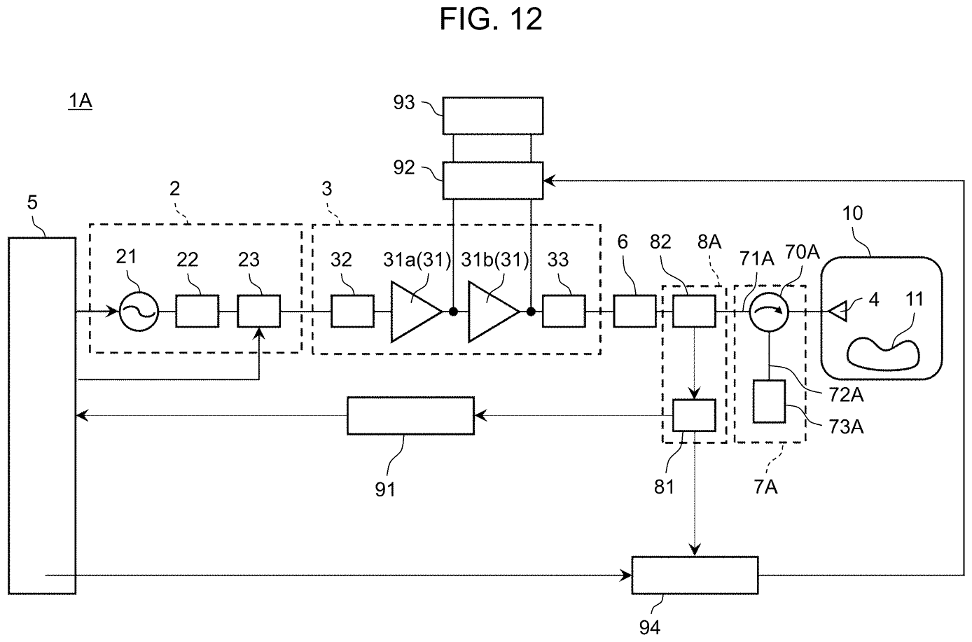

FIG. 12 is a schematic circuit diagram of radio wave radiator 1A according to a second exemplary embodiment of the present disclosure. As illustrated in FIG. 12, radio wave radiator 1A includes signal generator 2, signal amplifier 3, radio wave radiation unit 4, controller 5, filter circuit 6, and irreversible circuit 7A. In addition, radio wave radiator 1A includes traveling wave power measurement circuit 8A. Further, radio wave radiator 1A includes AD conversion circuit 91, bias voltage control circuit 92, DC power supply 93, and latch circuit 94.

Irreversible circuit 7A is disposed between filter circuit 6 and radio wave radiation unit 4. Irreversible circuit 7A transmits the traveling wave from filter circuit 6 to radio wave radiation unit 4, but does not transmit the reflected wave from radio wave radiation unit 4 to filter circuit 6. Irreversible circuit 7A is, for example, an isolator.

Irreversible circuit 7A includes circulator 70A and termination circuit 73A. Circulator 70A includes first transmission line 71A and second transmission line 72A. Termination circuit 73A is connected to second transmission line 72A. First transmission line 71A transmits the traveling wave to radio wave radiation unit 4, and second transmission line 72A transmits the reflected wave to termination circuit 73A.

Traveling wave power measurement circuit 8A measures traveling wave power. In the present exemplary embodiment, traveling wave power measurement circuit 8A is disposed on first transmission line 71A between filter circuit 6 and irreversible circuit 7A and measures traveling wave power.

With this configuration, traveling wave power measurement circuit 8A can measure the traveling wave power without being affected by the reflected wave. As a result, radio wave radiator 1A can improve the measurement accuracy of the traveling wave power.

Traveling wave power measurement circuit 8A includes detector circuit 81 and coupler 82. Coupler 82 detects a traveling wave. Coupler 82 is disposed between filter circuit 6 and irreversible circuit 7A. Coupler 82 is a directional coupler.

Detector circuit 81 measures traveling wave power. In the present exemplary embodiment, detector circuit 81 receives traveling wave coupling signal S12 (see FIG. 4) from coupler 82 and generates a traveling wave power measurement signal that is an analog signal corresponding to the traveling wave power based on traveling wave coupling signal S12. In the present exemplary embodiment, detector circuit 81 transmits the traveling wave power measurement signal to AD conversion circuit 91 and latch circuit 94.

AD conversion circuit 91 converts the traveling wave power measurement signal from detector circuit 81 into a digital signal and transmits the digital signal to controller 5.

Latch circuit 94 controls bias voltage control circuit 92. For example, when the traveling wave power measurement signal from detector circuit 81 has exceeded a threshold, latch circuit 94 turns off bias voltage control circuit 92. When receiving the reset signal from controller 5, latch circuit 94 turns on bias voltage control circuit 92.

Controller 5 controls signal generator 2 and signal amplifier 3 to cause radio wave radiation unit 4 to emit radio waves into cavity 10. In the present exemplary embodiment, controller 5 operates amplifier 31 of signal amplifier 3 in the saturation region. This can improve the power efficiency of amplifier 31.

Controller 5 receives the traveling wave power measurement signal converted into a digital signal by AD conversion circuit 91. Controller 5 may control signal generator 2 and signal amplifier 3 based on the traveling wave power indicated by the traveling wave power measurement signal.

For example, controller 5 may control signal generator 2 and signal amplifier 3 based on the traveling wave power indicated by the traveling wave power measurement signal and cause radio wave radiator 1A to perform a normal operation. In the normal operation, controller 5 may control signal generator 2 and signal amplifier 3 to adjust the traveling wave power to the target power.

### 1.2.2 Effects and the Like

As described above, radio wave radiator 1A includes traveling wave power measurement circuit 8A. Traveling wave power measurement circuit 8A is disposed between signal amplifier 3 and radio wave radiation unit 4 and measures traveling wave power. Controller 5 controls signal generator 2 and signal amplifier 3 based on the traveling wave power. This configuration can improve the accuracy of measurement of traveling wave power.

### 1.3 Third Exemplary Embodiment

### 1.3.1 Configuration

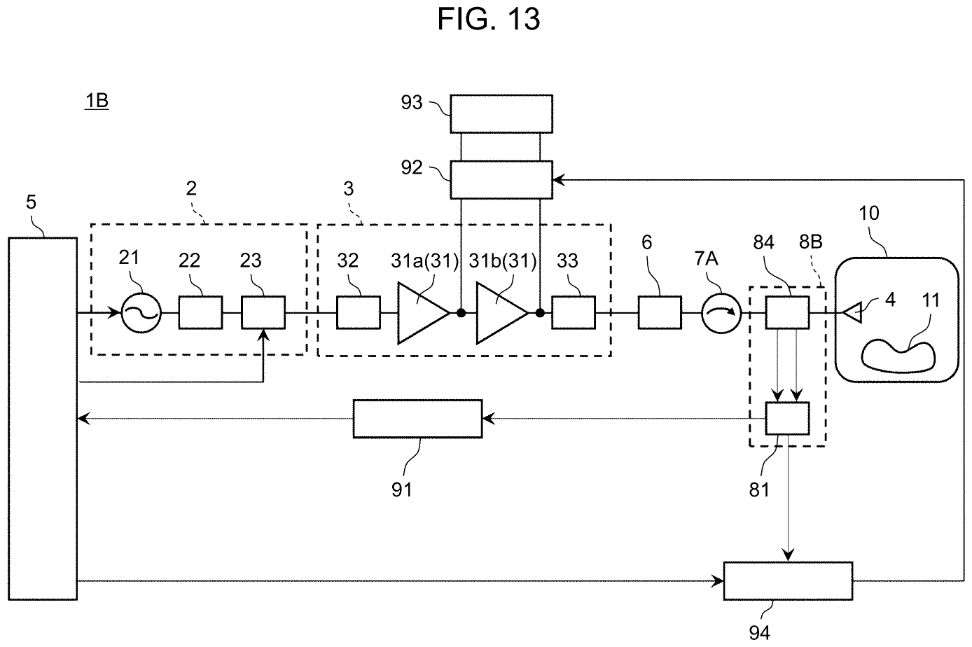

FIG. 13 is a schematic circuit diagram of radio wave radiator 1B according to a third exemplary embodiment of the present disclosure. As illustrated in FIG. 13, radio wave radiator 1B includes signal generator 2, signal amplifier 3, radio wave radiation unit 4, controller 5, filter circuit 6, and irreversible circuit 7A. In addition, radio wave radiator 1B includes power measurement circuit 8B. Further, radio wave radiator 1B includes AD conversion circuit 91, bias voltage control circuit 92, DC power supply 93, and latch circuit 94.

Power measurement circuit 8B measures traveling wave power and reflected wave power. Power measurement circuit 8B includes detector circuit 81 and coupler 84. Coupler 84 detects a traveling wave and a reflected wave. Coupler 84 is disposed between irreversible circuit 7A and radio wave radiation unit 4.

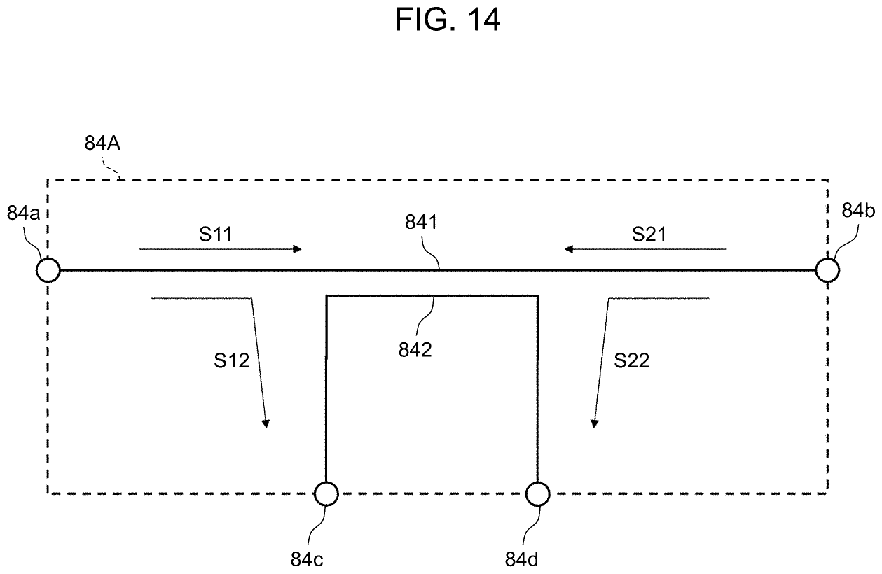

FIG. 14 is a schematic diagram of coupler 84A that is a first example of coupler 84. As illustrated in FIG. 14, coupler 84A is a bidirectional coupler. Coupler 84A includes first input and output port 84a, second input and output port 84b, first coupling port 84c, second coupling port 84d, first line 841, and second line 842.

First input and output port 84a is connected to irreversible circuit 7A, and second input and output port 84b is connected to radio wave radiation unit 4. First line 841 is disposed between first input and output port 84a and second input and output port 84b. Second line 842 is disposed between first coupling port 84c and second coupling port 84d, and is electromagnetically coupled partially parallel to first line 841.

Traveling wave S11 is input to first input and output port 84a and propagates through first line 841. Coupler 84A outputs a part of traveling wave S11 as traveling wave coupling signal S12 from first coupling port 84c via second line 842. The magnitude of traveling wave coupling signal S12 is proportional to the power of traveling wave S11.

Reflected wave S21 is input to second input and output port 84b and propagates through first line 841. Coupler 84A outputs a part of reflected wave S21 as reflected wave coupling signal S22 from second coupling port 84d via second line 842. The magnitude of reflected wave coupling signal S22 is proportional to the power of reflected wave S21.

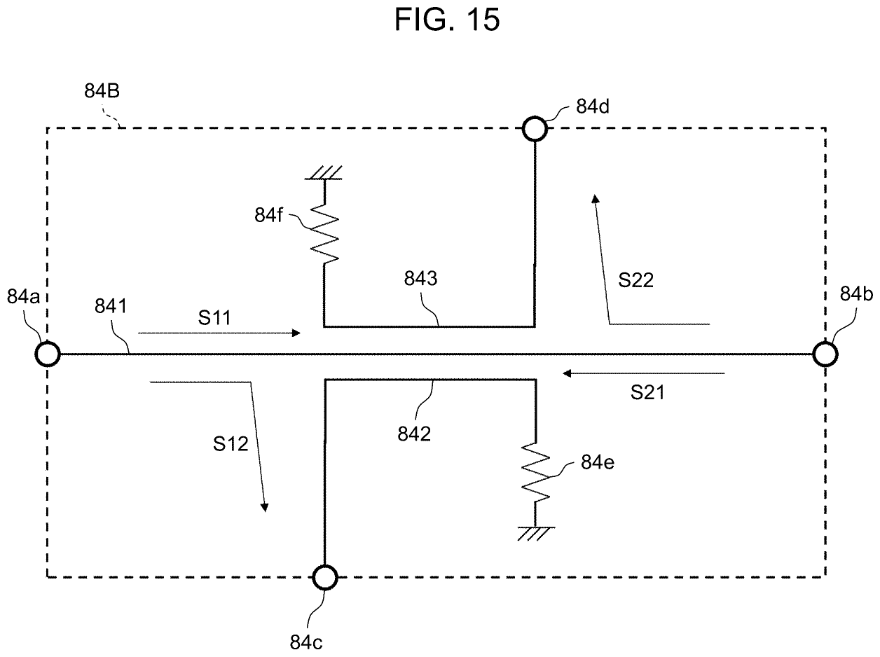

FIG. 15 is a schematic diagram of coupler 84B that is a second example of coupler 84. As illustrated in FIG. 15, coupler 84B is a dual-directional coupler. Coupler 84B includes first input and output port 84a, second input and output port 84b, first coupling port 84c, second coupling port 84d, first termination resistor 84e, second termination resistor 84f, first line 841, second line 842, and third line 843.

First input and output port 84a is connected to irreversible circuit 7A, and second input and output port 84b is connected to radio wave radiation unit 4. First line 841 is disposed between first input and output port 84a and second input and output port 84b. Second line 842 is disposed between first coupling port 84c and first termination resistor 84e, and is electromagnetically coupled partially parallel to first line 841.

Third line 843 is disposed between second coupling port 84d and second termination resistor 84f, and is electromagnetically coupled partially parallel to first line 841.

Traveling wave S11 is input to first input and output port 84a and propagates through first line 841. Coupler 84B outputs a part of traveling wave S11 as the traveling wave coupling signal S12 from first coupling port 84c via second line 842. The magnitude of traveling wave coupling signal S12 is proportional to the power of traveling wave S11.

Reflected wave S21 is input to second input and output port 84b and propagates through first line 841. Coupler 84B outputs a part of reflected wave S21 as reflected wave coupling signal S22 from second coupling port 84d via third line 843. The magnitude of reflected wave coupling signal S22 is proportional to the power of reflected wave S21.

Both coupler 84A illustrated in FIG. 14 and coupler 84B illustrated in FIG. 15 can detect the traveling wave and the reflected wave power. However, in coupler 84B, unlike coupler 84A, first coupling port 84c and second coupling port 84d are disposed on second line 842 and third line 843, respectively. That is, first coupling port 84c is disposed on a line different from the line on which second coupling port 84d is disposed.

With this configuration, coupler 84B can obtain higher directivity and isolation characteristics than coupler 84A. In addition, in coupler 84B, there is a lower possibility that mismatching in one line of two lines affects the other line than in coupler 84A.

The description returns to FIG. 13. Controller 5 controls signal generator 2 and signal amplifier 3 to cause radio wave radiation unit 4 to emit radio waves into cavity 10. In the present exemplary embodiment, controller 5 operates amplifier 31 of signal amplifier 3 in the saturation region. This can improve the power efficiency of amplifier 31.

Controller 5 receives the traveling wave power measurement signal and the reflected wave power measurement signal converted into digital signals by AD conversion circuit 91. Controller 5 may control signal generator 2 and signal amplifier 3 based on the traveling wave power indicated by the traveling wave power measurement signal and the reflected wave power indicated by the reflected wave power measurement signal.

### 1.3.2 Effects and the Like

As described above, radio wave radiator 1B includes power measurement circuit 8B. Power measurement circuit 8B is disposed between irreversible circuit 7A and radio wave radiation unit 4 and measures traveling wave power and reflected wave power. Controller 5 controls signal generator 2 and signal amplifier 3 based on the traveling wave power and the reflected wave power.

### 2. Modifications

The present disclosure is not limited to the above-described exemplary embodiments. Various modifications may be made to the exemplary embodiments as necessary as long as the object of the present disclosure can be achieved. Hereinafter, modifications of the exemplary embodiments will be listed.

### 2.1 First Modification

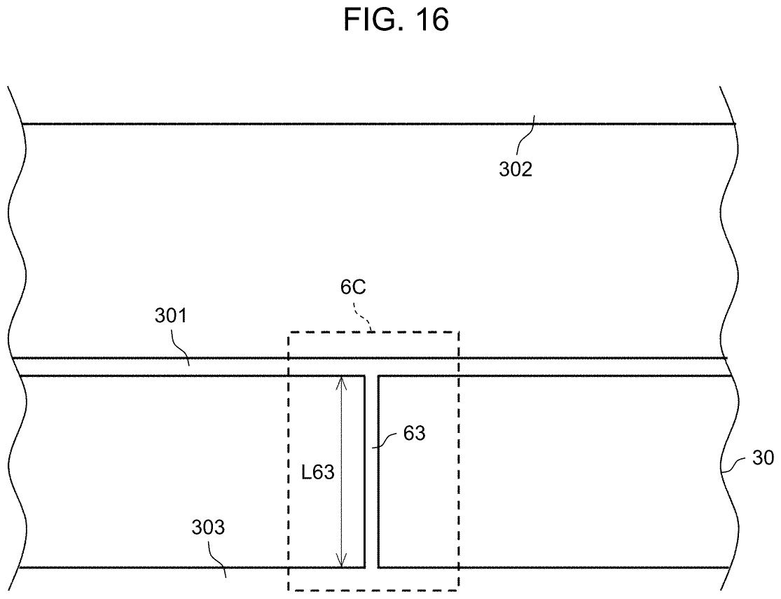

FIG. 16 is a schematic circuit diagram of filter circuit 6C according to a first modification. Filter circuit 6C can be used in place of or in addition to filter circuit 6 in the first to third exemplary embodiments.

As illustrated in FIG. 16, filter circuit 6C includes band-stop filter 63. Band-stop filter 63 is, for example, a short stub that attenuates the second harmonic of the high-frequency signal amplified by signal amplifier 3. Band-stop filter 63 includes, for example, a microstrip line extending from transmission line 301 to ground 303 and connected to ground 303.

Assuming that the length of band-stop filter 63 is L63, and the wavelength of the signal propagating through transmission line 301 is λ, band-stop filter 63 functions as an inductor when L63<λ/4. When L63=λ/4, band-stop filter 63 has an open impedance. When λ/4<L63<λ/2, band-stop filter 63 functions as a capacitor. When L63=λ/2, band-stop filter 63 has a short-circuit impedance.

Length L63 of band-stop filter 63 is set based on ¼ of wavelength λ of the high-frequency signal amplified by signal amplifier 3. Thus, band-stop filter 63 functions as an open impedance with respect to the high-frequency signal amplified by signal amplifier 3. On the other hand, band-stop filter 63 functions as a short-circuit impedance with respect to the second harmonic of the high-frequency signal amplified by signal amplifier 3.

As a result, band-stop filter 63 allows the high-frequency signal amplified by signal amplifier 3 to pass therethrough and attenuates the second harmonic of the high-frequency signal amplified by signal amplifier 3. For example, when the frequency of the high-frequency signal amplified by signal amplifier 3 is 2450 MHz, the frequency of the second harmonic wave is 4900 MHz.

### 2.2 Second Modification

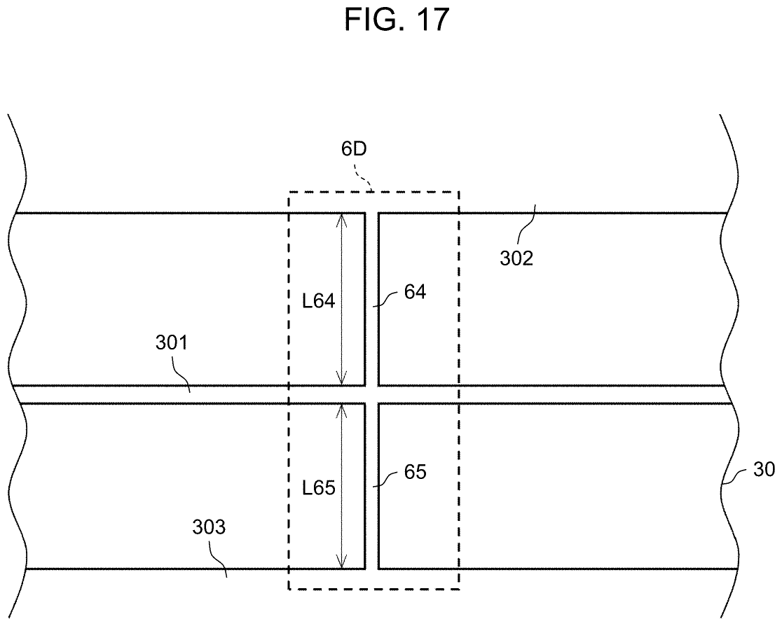

FIG. 17 is a schematic circuit diagram of filter circuit 6D of a second modification. Filter circuit 6D can be used in place of or in addition to filter circuit 6 in the first to third exemplary embodiments.

As illustrated in FIG. 17, filter circuit 6D includes band-stop filters 64 and 65. Band-stop filters 64 and 65 are, for example, short stubs that attenuate the second harmonic of the high-frequency signal amplified by signal amplifier 3.

Band-stop filter 64 includes, for example, a microstrip line extending from transmission line 301 to ground 302 and connected to ground 302. Band-stop filter 65 includes, for example, a microstrip line extending from transmission line 301 to ground 303 and connected to ground 303.

Assuming that the length of band-stop filter 64 is L64, and the wavelength of the signal propagating through transmission line 301 is λ, band-stop filter 64 functions as an inductor when L64<λ/4. When L64=λ/4, band-stop filter 64 has an open impedance. When λ/4<L64<λ/2, band-stop filter 64 functions as a capacitor. When L64=λ/2, band-stop filter 64 has a short-circuit impedance.

Assuming that the length of band-stop filter 65 is L65, and the wavelength of the signal propagating through transmission line 301 is λ, band-stop filter 65 functions as an inductor when L65<λ/4. When L65=λ/4, band-stop filter 65 has an open impedance. When λ/4<L65<λ/2, band-stop filter 65 functions as a capacitor. When L65=λ/2, band-stop filter 65 has a short-circuit impedance.

Lengths L64 and L65 are set based on ¼ of wavelength λ of the high-frequency signal amplified by signal amplifier 3. As a result, band-stop filters 64 and 65 function as open impedances with respect to the high-frequency signal amplified by signal amplifier 3. On the other hand, band-stop filters 64 and 65 function as short-circuit impedances with respect to the second harmonic of the high-frequency signal amplified by signal amplifier 3.

In the present exemplary embodiment, lengths L64 and L65 are different from each other. Specifically, L65<λ/4<L64 is satisfied. As a result, the stop bands of band-stop filters 64 and 65 partially overlap, and the stop band of filter circuit 6 is widened.

As described above, filter circuit 6D of FIG. 17 includes band-stop filters 64 and 65. Band-stop filters 64 and 65 are a plurality of distributed constant circuits in which stop bands partially overlap. With this configuration, the stop band of filter circuit 6 is widened, and the signal purity of the high-frequency signal transmitted to radio wave radiation unit 4 can be improved.

In FIG. 17, band-stop filters 64 and 65 are separately formed. However, band-stop filters 64 and 65 may be integrally formed. Band-stop filters 64 and 65 may be configured such that L64 and L65 are different from each other, for example, by sharing a connection point with transmission line 301 and having a path branching at a portion connected to ground 303.

Each of band-stop filters 64 and 65 includes a short stub. However, the length of the short stub included in band-stop filter 64 is different from the length of the short stub included in band-stop filter 65. With this configuration, filter circuit 6 can be downsized.

### 2.3 Third Modification

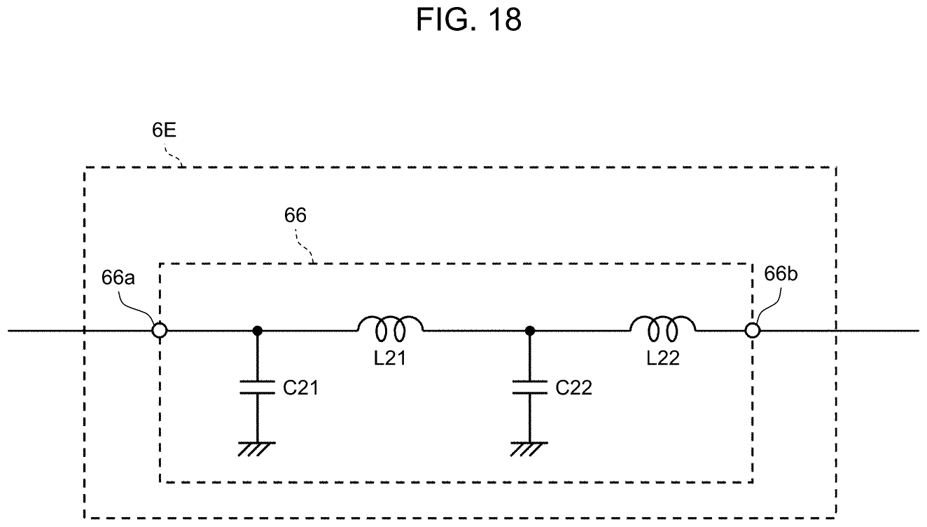

FIG. 18 is a schematic circuit diagram of filter circuit 6E of a third modification. Filter circuit 6E can be used in place of or in addition to filter circuit 6 in the first to third exemplary embodiments.

As illustrated in FIG. 18, filter circuit 6E includes low-pass filter 66. Low-pass filter 66 is a lumped constant circuit. Low-pass filter 66 attenuates a signal having a frequency higher than the frequency of the high-frequency signal amplified by signal amplifier 3. Low-pass filter 66 includes input terminal 66a, output terminal 66b, inductors L21 and L22, and capacitors C21 and C22.

Inductors L21 and L22 are connected in series between input terminal 66a and output terminal 66b. Capacitor C21 is disposed between the ground and the connection point between input terminal 66a and inductor L21. Capacitor C22 is disposed between the ground and the connection point between inductors L21 and L22.

Low-pass filter 66 functions as a matching circuit (for example, output matching circuit 33 of FIG. 1) with respect to amplifier 31 of signal amplifier 3. More specifically, low-pass filter 66 is configured using an inductor and a capacitor as described above. The inductor and the capacitor are used to set the output impedance of amplifier 31 to a predetermined impedance (for example, 50Ω).

Thus, low-pass filter 66 has a function as a matching circuit, more specifically, a function as output matching circuit 33 of FIG. 1. From another point of view, output matching circuit 33 of FIG. 1 has a function as a filter of filter circuit 6. The output matching circuit of signal amplifier 3 that handles high power is configured by a distributed constant circuit.

As described above, filter circuit 6E includes low-pass filter 66 that functions as a matching circuit with respect to amplifier 31 of signal amplifier 3. With this configuration, radio wave radiator 1 can be downsized. This configuration is suitable when radio wave radiator 1 handles large high-frequency power.

### 2.4 Fourth Modification

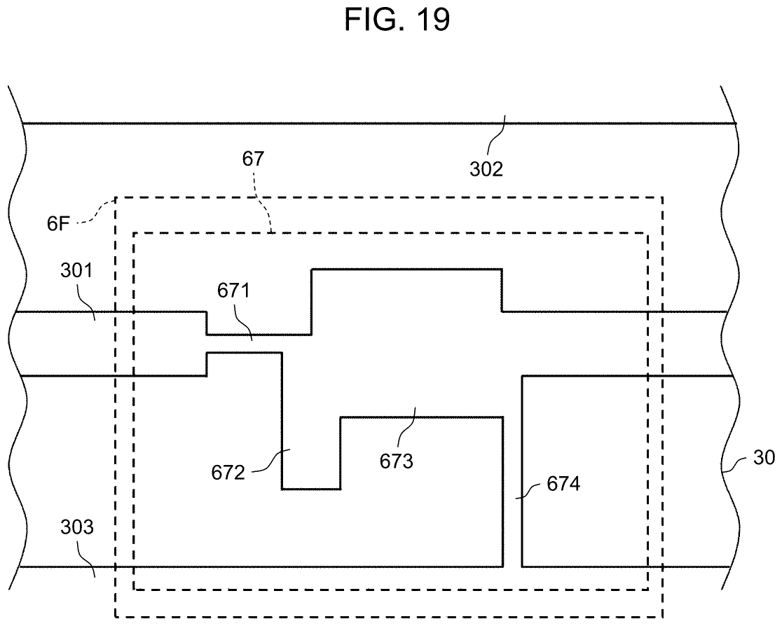

FIG. 19 is a schematic circuit diagram of filter circuit 6F according to a fourth modification. Filter circuit 6F can be used in place of or in addition to filter circuit 6 in the first to third exemplary embodiments.

As illustrated in FIG. 19, filter circuit 6F includes band-pass filter 67. Band-pass filter 67 is a distributed constant circuit. The band-pass filter 67 allows a high-frequency signal in a frequency band including the frequency of the high-frequency signal amplified by signal amplifier 3 to pass therethrough.

Band-pass filter 67 includes microstrip lines 671, 672, 673, and 674 constituting a part of transmission line 301. Microstrip lines 671, 672, 673, and 674 are made up of a conductor pattern formed on a printed circuit board.

Microstrip line 671 functions as an inductor inserted into transmission line 301. Microstrip line 672 functions as a capacitor between transmission line 301 and the ground. Microstrip line 673 functions as a capacitor inserted into transmission line 301. Microstrip line 674 functions as an inductor between transmission line 301 and the ground.

The inductance with microstrip lines 671 and 674 and the capacitance with microstrip lines 672 and 673 allow a high-frequency signal in a frequency band including the frequency of the high-frequency signal amplified by signal amplifier 3 to pass the lines.

### 2.5 Fifth Modification

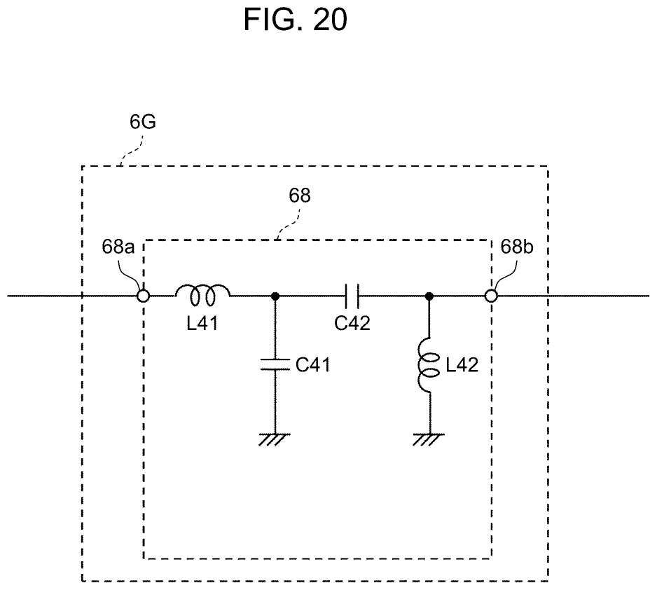

FIG. 20 is a schematic circuit diagram of filter circuit 6G of a fifth modification. Filter circuit 6G can be used in place of or in addition to filter circuit 6 in the first to third exemplary embodiments.

As illustrated in FIG. 20, filter circuit 6G includes band-pass filter 68. Band-pass filter 68 is a lumped constant circuit. When the wavelength of the high-frequency signal is sufficiently large with respect to the circuit shape and the shape of the circuit elements (circuit components), the lumped constant circuit can be used. In this case, the line connecting the circuit elements is sufficiently short as compared to the wavelength, and the phase difference can be ignored, thus the voltage and the current are considered to be constant at any position on the line.

In the lumped constant circuit, a constant value aggregated at one point of a circuit element can be used as it is. That is, in the lumped constant circuit, the resistance value of the resistor, the capacitance of the capacitor, and the inductance of the inductor can be used as they are.

Band-pass filter 68 allows a high-frequency signal in a frequency band including the frequency of the high-frequency signal amplified by signal amplifier 3 to pass therethrough. Band-pass filter 68 includes input terminal 68a, output terminal 68b, capacitors C41 and C42, and inductors L41 and L42.

Capacitor C41 is disposed between the ground and the connection point between input terminal 68a and output terminal 68b. Inductor L41 is disposed between input terminal 68a and capacitor C41. Capacitor C42 is disposed between capacitor C41 and output terminal 68b. Inductor L42 is disposed between the ground and the connection point between capacitor C42 and output terminal 68b.

### 2.6 Other Modifications

The configuration of signal generator 2, the configuration of signal amplifier 3, and the configuration of radio wave radiation unit 4 are not limited to the above-described exemplary embodiments. Signal generator 2 may generate a plurality of high-frequency signals having different frequencies. In signal amplifier 3, at least one of the plurality of amplifiers may be amplifier 31 having a transistor. The number of signal generators 2, the number of signal amplifiers 3, and the number of radio wave radiation units 4 are also not particularly limited.

The operation of controller 5 is not limited to the above-described exemplary embodiments. Controller 5 does not have to operate all of amplifiers 31a and 31b of signal amplifier 3 in the saturation region. The operation of controller 5 described in the exemplary embodiments is merely an example, and controller 5 may execute various known operations.

Filter circuit 6 is disposed between amplifier 31 (in particular, amplifier 31b) of signal amplifier 3 and radio wave radiation unit 4, allows the high-frequency signal amplified by signal amplifier 3 to pass therethrough, and attenuates unnecessary radiation generated in signal amplifier 3.

Filter circuit 6 includes one or more filters. Each filter may be a distributed constant circuit or a lumped constant circuit. Filter circuit 6 includes at least one of a distributed constant circuit and a lumped constant circuit. This configuration can improve the signal purity of the high-frequency signal transmitted to radio wave radiation unit 4.

Filter circuit 6 includes at least one of a band-pass filter, a band-stop filter, and a low-pass filter. This configuration can improve the signal purity of the high-frequency signal transmitted to radio wave radiation unit 4.

Irreversible circuit 7 is disposed between filter circuit 6 and radio wave radiation unit 4 to reduce the fluctuation in characteristics of filter circuit 6. Irreversible circuit 7 is made up of, for example, a circulator or an isolator. However, irreversible circuit 7 is not limited to this configuration, and it is sufficient that filter circuit 6 and radio wave radiation unit 4 can be connected such that the load impedance does not substantially change as viewed from filter circuit 6.

The configurations of traveling wave power measurement circuit 8a, reflected wave power measurement circuit 8b, traveling wave power measurement circuit 8A, and power measurement circuit 8B are not limited to the above-described exemplary embodiments. For example, it is not essential to use any one of a directional coupler, a bidirectional coupler, and a dual coupler.

In the first exemplary embodiment, traveling wave power measurement circuit 8a is disposed between filter circuit 6 and irreversible circuit 7. However, the position of traveling wave power measurement circuit 8a is not limited as long as the traveling wave power measurement circuit 8a is disposed between signal amplifier 3 and irreversible circuit 7. That is, traveling wave power measurement circuit 8a may be disposed at a preceding stage of filter circuit 6.

AD conversion circuit 91, bias voltage control circuit 92, DC power supply 93, and latch circuit 94 are optional elements.

Radio wave radiator 1 may include an additional processing means. The processing means may be heating means or radio wave emission means. The heating means is, for example, a heater. In this case, processing in which the heater and radio wave radiation unit 4 are combined can be executed. The radio wave emission means is, for example, a magnetron. In this case, processing in which the magnetron and radio wave radiation unit 4 are combined can be executed.

### 3. Aspects

Radio wave radiator (1; 1A; 1B) according to a first aspect includes cavity (10), signal generator (2), signal amplifier (3), radio wave radiation unit (4), controller (5), filter circuit (6; 6C; 6D; 6E; 6F; 6G), and irreversible circuit (7; 7A).

Signal generator (2) generates a high-frequency signal. Signal amplifier (3) includes amplifier (31) and amplifies the high-frequency signal. Radio wave radiation unit (4) emits a radio wave into cavity (10) based on the high-frequency signal amplified by signal amplifier (3). Controller (5) controls signal generator (2) and signal amplifier (3).

Filter circuit (6; 6C; 6D; 6E; 6F; 6G) is disposed between amplifier (31) and radio wave radiation unit (4), allows the high-frequency signal amplified by signal amplifier (3) to pass therethrough, and attenuates unnecessary radiation generated in signal amplifier (3). Irreversible circuit (7; 7A) is disposed between filter circuit (6; 6C; 6D; 6E; 6F; 6G) and radio wave radiation unit (4).

The present aspect can improve the signal purity of the high-frequency signal transmitted to radio wave radiation unit (4).

In radio wave radiator (1; 1A; 1B) according to a second aspect, based on the first aspect, controller (5) operates amplifier (31) of signal amplifier (3) in a saturation region. The present aspect can improve the power efficiency of signal amplifier (3).

In radio wave radiator (1; 1A; 1B) according to a third aspect, the unnecessary radiation includes harmonics of the high-frequency signal generated when amplifier (31) of signal amplifier (3) operates in the saturation region. The present aspect can improve the signal purity of the high-frequency signal transmitted to radio wave radiation unit (4).

Radio wave radiator (1; 1A; 1B) according to a fourth aspect further includes, based on any one of the first to third aspects, traveling wave power measurement circuit (8a) and reflected wave power measurement circuit (8b). Traveling wave power measurement circuit (8a) measures traveling wave power that is power of a traveling wave, the traveling wave being the high-frequency signal amplified by signal amplifier (3). Reflected wave power measurement circuit (8b) measures reflected wave power that is power of a reflected wave flowing backward from radio wave radiation unit (4).

Irreversible circuit (7) includes first transmission line (71) and second transmission line (72) insulated from each other. First transmission line (71) transmits the traveling wave to radio wave radiation unit (4). Second transmission line (72) transmits the reflected wave to termination circuit (95).

Traveling wave power measurement circuit (8a) measures the traveling wave power in first transmission line (71). Reflected wave power measurement circuit (8b) measures the reflected wave power in second transmission line (72). Controller (5) controls signal generator (2) and signal amplifier (3) based on the traveling wave power and the reflected wave power. The present aspect can improve the accuracy of measurement of traveling wave power and reflected wave power.

Radio wave radiator (1A) according to a fifth aspect further includes, based on any one of the first to third aspects, traveling wave power measurement circuit (8A). Traveling wave power measurement circuit (8A) is disposed between signal amplifier (3) and radio wave radiation unit (4) and measures traveling wave power that is power of a traveling wave, the traveling wave being the high-frequency signal amplified by signal amplifier (3).

Controller (5) controls signal generator (2) and signal amplifier (3) based on the traveling wave power. The present aspect can improve the accuracy of measurement of traveling wave power.

Radio wave radiator (1B) according a sixth aspect further includes, based on any one of the first to third aspects, power measurement circuit (8B). Power measurement circuit (8B) is disposed between irreversible circuit (7A) and radio wave radiation unit (4) and measures traveling wave power that is power of a traveling wave, the traveling wave being the high-frequency signal amplified by signal amplifier (3), and reflected wave power that is power of a reflected wave flowing backward from radio wave radiation unit (4).

Controller (5) controls signal generator (2) and signal amplifier (3) based on the traveling wave power and the reflected wave power. The present aspect can improve the accuracy of measurement of traveling wave power and reflected wave power.

In radio wave radiator (1; 1A; 1B) according to a seventh aspect, based on any one of the first to sixth aspects, filter circuit (6; 6C; 6D; 6E; 6F; 6G) includes at least one of band-pass filter (67, 68), band-stop filter (61, 62, 63, 64, 65), and low-pass filter (66). The present aspect can improve the signal purity of the high-frequency signal transmitted to radio wave radiation unit (4).

In radio wave radiator (1; 1A; 1B) according to an eighth aspect, based on any one of the first to seventh aspects, filter circuit (6; 6C; 6D; 6E; 6F; 6G) includes at least one of distributed constant circuit (61, 62, 63, 64, 65, 66, 67) and lumped constant circuit (68). The present aspect can improve the signal purity of the high-frequency signal transmitted to radio wave radiation unit (4).

In radio wave radiator (1; 1A; 1B) according a ninth aspect, based on any one of the first to eighth aspects, filter circuit (6; 6C; 6D; 6E; 6F) includes distributed constant circuit (61, 62, 63, 64, 65, 66, 67). Distributed constant circuit (61, 62, 63, 64, 65, 66, 67) is disposed on circuit board (300) of signal amplifier (3). The present aspect can downsize radio wave radiator (1; 1A; 1B).

In radio wave radiator (1; 1A; 1B) according a tenth aspect, based on any one of the first to ninth aspects, filter circuit (6E) includes low-pass filter (66) that functions as a matching circuit with respect to amplifier (31) of signal amplifier (3). The present aspect can downsize radio wave radiator (1; 1A; 1B).

In radio wave radiator (1; 1A; 1B) according an eleventh aspect, based on any one of the first to tenth aspects, filter circuit (6D) includes a plurality of band-stop filters (64, 65). The plurality of band-stop filters (64, 65) are a plurality of distributed constant circuits (64, 65) in which stop bands partially overlap.

The present aspect can widen the stop band of filter circuit (6D) and improve the signal purity of the high-frequency signal to be transmitted to radio wave radiation unit (4).

In radio wave radiator (1; 1A; 1B) according a twelfth aspect, based on the eleventh aspect, the plurality of distributed constant circuits (64, 65) include a plurality of short stubs (64, 65) each having a different length. The present aspect can downsize filter circuit (6D).

In radio wave radiator (1; 1A; 1B) according a thirteenth aspect, based on any one of the first to twelfth aspects, filter circuit (6) includes distributed constant circuit (61, 62) constituting a band-stop filter that attenuates harmonics of the high-frequency signal. The present aspect can downsize filter circuit (6).

In radio wave radiator (1; 1A; 1B) according a fourteenth aspect, based on the thirteenth aspect, distributed constant circuit (61, 62) includes short stub (61) and open stub (62). Short stub (61) attenuates a second harmonic of the high-frequency signal. Open stub (62) attenuates a third harmonic of the high-frequency signal. The present aspect can downsize filter circuit (6).

Radio wave radiator (1; 1A; 1B) according to a fifteenth aspect includes cavity (10), signal generator (2), signal amplifier (3), radio wave radiation unit (4), controller (5), filter circuit (6; 6C; 6D; 6E; 6F; 6G), and irreversible circuit (7; 7A).

Signal generator (2) generates a high-frequency signal. Signal amplifier (3) includes amplifier (31) and amplifies the high-frequency signal. Radio wave radiation unit (4) emits a radio wave into cavity (10) based on the high-frequency signal amplified by signal amplifier (3). Controller (5) controls signal generator (2) and signal amplifier (3).

Filter circuit (6; 6C; 6D; 6E; 6F; 6G) allows the high-frequency signal amplified by signal amplifier (3) to pass therethrough and attenuates unnecessary radiation generated in signal amplifier (3). Irreversible circuit (7; 7A) reduces a fluctuation in characteristics of filter circuit (6; 6C; 6D; 6E; 6F; 6G).

The present aspect can improve the signal purity of the high-frequency signal transmitted to radio wave radiation unit (4).

The second to fourteenth aspects are not essential but optional. The second to fourteenth aspects can be appropriately combined with the fifteenth aspect.

### INDUSTRIAL APPLICABILITY

The present disclosure is applicable to a radio wave radiator that emits a radio wave based on a high-frequency signal amplified by a signal amplifier.

### REFERENCE MARKS IN THE DRAWINGS

1, 1A, 1B: radio wave radiator
2: signal generator
21: oscillation circuit
22: matching circuit
23: variable amplifier
3: signal amplifier
30: circuit board
301: transmission line
302, 303: ground
31, 31a, 31b: amplifier
311: transistor
312, 313: choke circuit
32: input matching circuit
33: output matching circuit
4: radio wave radiation unit
5: controller
6, 6C, 6D, 6E, 6F, 6G: filter circuit
61, 62, 63, 64, 65: band-stop filter (distributed constant circuit)
66: low-pass filter (lumped constant circuit)
66a: input terminal
66b: output terminal
67: band-pass filter (distributed constant circuit)
671, 672, 673, 674: microstrip line
68: band-pass filter (lumped constant circuit)
68a: input terminal
68b: output terminal
7, 7A: irreversible circuit
70A: circulator
71, 71A: first transmission line
72, 72A: second transmission line
73A, 95: termination circuit
8a: traveling wave power measurement circuit
8b: reflected wave power measurement circuit
8A: traveling wave power measurement circuit
8B: power measurement circuit
81: detector circuit
82, 83, 84, 84A, 84B: coupler
821, 822, 831, 832, 841, 842, 843: line
82a, 83a: input port
82b, 83b: output port
82c, 83c, 84c, 84d: coupling port
82d, 83d, 84e, 84f: termination resistor
84a, 84b: input and output port
91: AD conversion circuit
92: bias voltage control circuit
93: DC power supply
94: latch circuit
10: cavity
11: irradiation target

1. A radio wave radiator comprising:
a cavity;
a signal generator configured to generate a high-frequency signal;
a signal amplifier including an amplifier, the signal amplifier being configured to amplify the high-frequency signal;
a radio wave radiation unit configured to emit a radio wave into the cavity based on the high-frequency signal amplified by the signal amplifier;
a controller configured to control the signal generator and the signal amplifier;
a filter circuit disposed between the amplifier and the radio wave radiation unit, the filter circuit being configured to allow the high-frequency signal amplified by the signal amplifier to pass through the filter circuit and attenuate unnecessary radiation generated by the signal amplifier; and
an irreversible circuit disposed between the filter circuit and the radio wave radiation unit.

2. The radio wave radiator according to claim 1, wherein the controller is configured to operate the amplifier of the signal amplifier in a saturation region.

3. The radio wave radiator according to claim 2, wherein the unnecessary radiation includes harmonics of the high-frequency signal generated when the amplifier of the signal amplifier operates in the saturation region.

4. The radio wave radiator according to claim 1, the radio wave radiator further comprising:
a traveling wave power measurement circuit configured to measure traveling wave power that is power of a traveling wave, the traveling wave being the high-frequency signal amplified by the signal amplifier; and
a reflected wave power measurement circuit configured to measure reflected wave power that is power of a reflected wave flowing backward from the radio wave radiation unit,
wherein
the irreversible circuit includes a first transmission line and a second transmission line insulated from each other,
the first transmission line transmits the traveling wave to the radio wave radiation unit,
the second transmission line transmits the reflected wave to a termination circuit,
the traveling wave power measurement circuit is configured to measure the traveling wave power in the first transmission line,
the reflected wave power measurement circuit is configured to measure the reflected wave power in the second transmission line, and
the controller is configured to control the signal generator and the signal amplifier based on the traveling wave power and the reflected wave power.

5. The radio wave radiator according to claim 1, the radio wave radiator further comprising a traveling wave power measurement circuit that is disposed between the signal amplifier and the radio wave radiation unit and measures traveling wave power that is power of a traveling wave, the traveling wave being the high-frequency signal amplified by the signal amplifier,
wherein the controller is configured to control the signal generator and the signal amplifier based on the traveling wave power.

6. The radio wave radiator according to claim 1, the radio wave radiator further comprising a power measurement circuit that is disposed between the irreversible circuit and the radio wave radiation unit and measures traveling wave power that is power of a traveling wave, the traveling wave being the high-frequency signal amplified by the signal amplifier, and reflected wave power that is power of a reflected wave flowing backward from the radio wave radiation unit,
wherein the controller controls the signal generator and the signal amplifier based on the traveling wave power and the reflected wave power.

7. The radio wave radiator according to claim 1, wherein the filter circuit includes at least one of a band-pass filter, a band-stop filter, and a low-pass filter.

8. The radio wave radiator according to claim 1, wherein the filter circuit includes at least one of a distributed constant circuit and a lumped constant circuit.

9. The radio wave radiator according to claim 1, wherein
the filter circuit includes a distributed constant circuit, and
the distributed constant circuit is disposed on a circuit board of the signal amplifier.

10. The radio wave radiator according to claim 1, wherein the filter circuit includes a low-pass filter that functions as a matching circuit with respect to the amplifier of the signal amplifier.

11. The radio wave radiator according to claim 1, wherein
the filter circuit includes a plurality of band-stop filters, and
the plurality of band-stop filters are a plurality of distributed constant circuits in which stop bands partially overlap.

12. The radio wave radiator according to claim 11, wherein the plurality of distributed constant circuits include a plurality of short stubs each having a different length.

13. The radio wave radiator according to claim 1, wherein the filter circuit includes a distributed constant circuit constituting a band-stop filter that attenuates harmonics of the high-frequency signal.

14. The radio wave radiator according to claim 13, wherein
the distributed constant circuit includes:
a short stub that attenuates a second harmonic of the high-frequency signal; and
an open stub that attenuates a third harmonic of the high-frequency signal.

15. A radio wave radiator comprising:
a cavity;
a signal generator configured to generate a high-frequency signal;
a signal amplifier including an amplifier, the signal amplifier being configured to amplify the high-frequency signal;
a radio wave radiation unit configured to emit a radio wave into the cavity based on the high-frequency signal amplified by the signal amplifier;
a controller configured to control the signal generator and the signal amplifier;
a filter circuit configured to allow the high-frequency signal amplified by the signal amplifier to pass through the filter circuit and attenuate unnecessary radiation generated by the signal amplifier; and
an irreversible circuit configured to reduce a fluctuation in characteristics of the filter circuit.
